(19) United States
(12) Patent Application Publication
(10) Pub. No.: US 2005/0040410 A1
(43) Pub. Date: Feb. 24, 2005

(54) Tilted cavity semiconductor optoelectronic device and method of making same

(75) Inventors: Nikolai Ledentsov, Berlin (DE); Vitaly Shchukin, Berlin (DE)

Correspondence Address: BROWN & MICHAELS, PC;400 M & T BANK BUILDING, 118 NORTH TIOGA ST, ITHACA, NY, 14850, US

(73) Assignee: NL-Nanosemiconductor GmbH, Dortmund (DE)

(21) Appl. No.: 10/943,044

(22) Filed: Sep. 16, 2004

Related U.S. Application Data
(63) Continuation-in-part of application No. 10/074,493, filed on Feb. 12, 2002.
(60) Provisional application No. 60/526,409, filed on Dec. 1, 2003.
(60) Provisional application No. 60/560,149, filed on Apr. 7, 2004.

(51) Int. Cl. H01L 27/15; H01S 5/00; H01L 33/00

(52) U.S. Cl. 257/79; 372/43; 372/44; 257/94

(57) ABSTRACT

A novel class of semiconductor light-emitting devices, or “tilted cavity light-emitting devices” is disclosed. The device includes at least one active element, generally placed within a cavity, with an active region generating an optical gain by injection of a current and two mirrors. The device generates optical modes that propagate in directions, which are tilted with respect to both the p-n junction plane and the direction normal to this plane. A light-emitting diode is also disclosed, where the cavity and the mirrors are designed such that transmission of generated optical power within a certain spectral range and within a certain interval of angles to the substrate is minimized. Transmission of optical power within a certain spectral range, which corresponds to the emission range of the light-emitting active medium and within a certain interval of angles out of the device, is optimized to achieve a required output power level.

### REFERENCE TO RELATED APPLICATIONS

This application claims an invention which was disclosed in provisional application No. 60/526,409, filed Dec. 1, 2003, entitled “Tilted Cavity Semiconductor Light-Emitting Device and Method of Making Same” and Provisional Application No. 60/560,149, filed Apr. 7, 2004, entitled “Optoelectronic Device Based on an Antiwaveguiding Cavity”. The benefit under 35 USC §119(e) of the United States provisional applications is hereby claimed, and the aforementioned applications are hereby incorporated herein by reference.

This is also a continuation-in-part patent application of copending application Ser. No. 10/074,493, filed Feb. 12, 2002, entitled “Tilted Cavity Semiconductor Laser (TCSL) and Method of Making Same”. The benefit under 35 USC §120 of the parent United States patent application is hereby claimed, and the aforementioned application is hereby incorporated herein by reference.

### BACKGROUND OF THE INVENTION

1. Field of the Invention

The invention pertains to the field of semiconductor devices. More particularly, the invention pertains to light-emitting diodes, wavelength-stabilized semiconductor edge-emitting and surface-emitting lasers, optical amplifiers, photodetectors, and mode-locked lasers.

2. Description of Related Art

A prior art semiconductor diode laser, or more specifically, edge-emitting laser, is shown in FIG. 1(a). The laser structure (100) is grown epitaxially on an n-doped substrate (101). The structure further includes an n-doped cladding layer (102), a waveguide (103), a p-doped cladding layer (108), and a p-contact layer (109). The waveguide (103) includes an n-doped layer (104), a confinement layer (105) with an active region (106) inside the confinement layer, and a p-doped layer (107). The n-contact (111) is contiguous with the substrate (101). A p-contact (112) is mounted on the p-contact layer (109). The active region (106) generates light when a forward bias (113) is applied. The profile of the optical mode in the vertical direction z is determined by the refractive index profile in the z-direction. The waveguide (103) is bounded in the lateral plane by a front facet (116) and a rear facet (117). If a special highly reflecting coating is put on the rear facet (117), the laser light (115) is emitted only through the front facet (116).

The substrate (101) is formed from any III-V semiconductor material or III-V semiconductor alloy. For example, GaAs, InP, GaSb. GaAs or InP are generally used depending on the desired emitted wavelength of laser radiation. Alternatively, sapphire, SiC or [111]-Si is used as a substrate for GaN-based lasers, i.e. laser structures, the layers of which are formed of GaN, AlN, InN, or alloys of these materials. The substrate (101) is doped by an n-type, or donor impurity. Possible donor impurities include, but are not limited to S, Se, Te, and amphoteric impurities like Si, Ge, Sn, where the latter are introduced under such technological conditions that they are incorporated predominantly into the cation sublattice to serve as donor impurities.

The n-doped cladding layer (102) is formed from a material lattice-matched or nearly lattice-matched to the substrate (101), is transparent to the generated light, and is doped by a donor impurity. In the case of a GaAs substrate (101), the n-doped cladding layer is preferably formed of a GaAlAs alloy.

The n-doped layer (104) of the waveguide (103) is formed from a material lattice-matched or nearly lattice-matched to the substrate (101), is transparent to the generated light, and is doped by a donor impurity. In the case of a GaAs substrate, the n-doped layer (104) of the waveguide is preferably formed of GaAs or of a GaAlAs alloy having an Al content lower than that in the n-doped cladding layer (102).

The p-doped layer (107) of the waveguide (103) is formed from a material lattice-matched or nearly lattice-matched to the substrate (101), is transparent to the generated light, and is doped by an acceptor impurity. Preferably, the p-doped layer (107) of the waveguide is formed from the same material as the n-doped layer (104) but doped by an acceptor impurity. Possible acceptor impurities include, but are not limited to, Be, Mg, Zn, Cd, Pb, Mn and amphoteric impurities like Si, Ge, Sn, where the latter are introduced under such technological conditions that they are incorporated predominantly into the anion sublattice and serve as acceptor impurities.

The p-doped cladding layer (108) is formed from a material lattice-matched or nearly lattice-matched to the substrate (101), transparent to the generated light, and doped by an acceptor impurity. Preferably, the p-doped cladding layer (108) is formed from the same material as the n-doped cladding layer (102), but is doped by an acceptor impurity.

The p-contact layer (109) is preferably formed from a material lattice-matched or nearly lattice matched to the substrate, is transparent to the generated light, and is doped by an acceptor impurity. The doping level is preferably higher than that in the p-cladding layer (108).

The metal contacts (111) and (112) are preferably formed from the multi-layered metal structures. The metal contact (111) is preferably formed from a structure including, but not limited to the structure Ni—Au—Ge. Metal contacts (112) are preferably formed from a structure including, but not limited to, the structure Ti—Pt—Au.

The confinement layer (105) is formed from a material lattice-matched or nearly lattice-matched to the substrate (101), is transparent to the generated light, and is either undoped or weakly doped. The confinement layers are preferably formed from the same material as the substrate (101).

The active region (106) placed within the confinement layer (105) is preferably formed by any insertion, the energy band gap of which is narrower than that of the substrate (101). Possible active regions (106) include, but are not limited to, a single-layer or a multi-layer system of quantum wells, quantum wires, quantum dots, or any combination thereof. In the case of a device on a GaAs-substrate, examples of the active region (106) include, but are not limited to, a system of insertions of InAs, In₁₋ₓGaₓAs, InₓGa_{1-x-y}Al_{y}As, InₓGa₁₋ₓAs_{1-y}N_{y} or similar materials.

One of the major shortcomings of the edge-emitting laser of the prior art is the variation of the energy band gap with temperature resulting in an undesirable temperature dependence of the wavelength of emitted light, particularly for high output power operation.

FIG. 1(b) shows schematically a prior art surface-emitting laser, particularly, a vertical cavity surface-emitting laser (VCSEL) (120). The active region (126) is put into a cavity (123), which is sandwiched between an n-doped bottom mirror (122) and a p-doped top mirror (128). The cavity (123) includes an n-doped layer (124), a confinement layer (125), and a p-doped layer (127). Bragg reflectors each including a periodic sequence of alternating layers having low and high refractive indices are used as a bottom mirror (122) and a top mirror (128). The active region (125) generates light when a forward bias (113) is applied. Light comes out (135) through the optical aperture (132). The wavelength of the emitted laser light from the VCSEL is determined by the length of the cavity (123).

The layers forming the bottom mirror (122) are formed from materials lattice-matched or nearly lattice matched to the substrate (101), are transparent to the generated light, are doped by a donor impurity, and have alternating high and low refractive indices. For a VCSEL grown on a GaAs substrate, alternating layers of GaAs and GaAlAs or layers of GaAlAs having alternating aluminum content preferably form the mirror (122).

The n-doped layer (124) of the cavity (123) is formed from a material lattice-matched or nearly lattice-matched to the substrate (101), is transparent to the generated light, and is doped by a donor impurity.

The p-doped layer (127) of the cavity (123) is formed from a material lattice-matched or nearly lattice-matched to the substrate (101), is transparent to the generated light, and is doped by an acceptor impurity.

The layers forming the top mirror (128) are formed from materials lattice-matched or nearly lattice-matched to the substrate (101), are transparent to the generated light, are doped by an acceptor impurity, and have alternating high and low refractive indices. For a VCSEL grown on a GaAs substrate, alternating layers of GaAs and GaAlAs or layers of GaAlAs having alternating aluminum content preferably form the mirror (128).

The p-contact layer (129) is formed from a material doped by an acceptor impurity. For a VCSEL grown on a GaAs substrate, the preferred material is GaAs. The doping level is preferably higher than that in the top mirror (128). The p-contact layer (129) and the metal p-contact (112) are etched to form an optical aperture (132).

The confinement layer (125) is formed from a material lattice-matched or nearly lattice-matched to the substrate (101), is transparent to the generated light, and is either undoped or weakly doped. The confinement layers are preferably formed from the same material as the substrate (101).

The active region (126) placed within the confinement layer (125) is preferably formed by any insertion, the energy band gap of which is narrower than that of the substrate (101). Possible active regions (126) include, but are not limited to, a single-layer or a multi-layer system of quantum wells, quantum wires, quantum dots, or any combination thereof. In the case of a device on a GaAs-substrate, examples of the active region (126) include, but are not limited to, a system of insertions of InAs, In₁₋ₓGaₓAs, InₓGa_{1-x-y}Al_{y}As, InₓGa₁₋ₓAs_{1-y}N_{y} or similar materials.

The active region (126) generates optical gain when a forward bias (113) is applied. The active region (126) then emits light, which is bounced between the bottom mirror (122) and the top mirror (128). The mirrors have high reflectivity for light propagating in the normal direction to the p-n junction plane, and the reflectivity of the bottom mirror (122) is higher than that of the top mirror (128). Thus, the VCSEL design provides a positive feedback for light propagating in the vertical direction and finally results in lasing. The laser light (135) comes out through the optical aperture (132).

One of the major advantages of a VCSEL is the temperature stabilization of the wavelength if the device operates in a single transverse mode. Temperature variations of the wavelength follow the temperature variations of the refractive index, which are an order of magnitude smaller than the variations of the semiconductor band gap energy. A severe disadvantage of a VCSEL is that its output power is limited to a few milliwatts, because it is not possible to provide efficient heat dissipation in the VCSEL geometry keeping a single transverse mode operation.

FIG. 2 shows schematically a prior art light-emitting diode (200). The structure is grown epitaxially on an n-doped substrate (101), and includes an n-doped region (202), a confinement layer (205), a p-doped region (208), and a p-contact layer (209). The confinement layer (205) further includes an active region (206). The active region (206) generates an optical gain when a forward bias (113) is applied. Electrons from the n-doped region (202) and holes from the p-doped region (208) are injected into the confinement layer (205) and recombine in the active region (206), thereby emitting light. Light is generated, as a rule, in a broad spectrum of wavelengths in all spatial directions.

The n-doped layer (202) is formed from a material lattice-matched or nearly lattice-matched to the substrate (101), is doped by an n-impurity, and is preferably transparent to the emitted light in the broad spectral region, in which the optical gain in the active region (206) occurs. In the case of a GaAs substrate, the n-doped layer (202) is preferably formed from an n-doped GaAlAs alloy.

The p-doped layer (208) is formed from a material lattice-matched or nearly lattice-matched to the substrate (101), is doped by a p-impurity, and is preferably transparent to the emitted light in the broad spectral region, in which the optical gain in the active region (206) occurs. In the case of a GaAs substrate, the p-doped layer (208) is preferably formed from a p-doped GaAlAs alloy.

The p-contact layer (209) is preferably formed from a material lattice-matched or nearly lattice matched to the substrate, is transparent to the generated light, and is doped by an acceptor impurity. The doping level is preferably higher than that in the p-doped layer (208).

The confinement region (205) is formed from a material lattice-matched or nearly lattice-matched to the substrate, is transparent to the emitted light, and is either undoped or weakly doped. In the case of a GaAs substrate, the preferred material is also GaAs.

The active region (206) placed within the confinement layer (205) is preferably formed by any insertion, the energy band gap of which is narrower than that of the substrate (101). Possible active regions (206) include, but are not limited to, a single-layer or a multi-layer system of quantum wells, quantum wires, quantum dots, or any combination thereof. In the case of a device on a GaAs-substrate, examples of the active region (206) include, but are not limited to, a system of insertions of InAs, In₁₋ₓGaₓAs, InₓGa_{1-x-y}Al_{y}As, InₓGa₁₋ₓAs_{1-y}N_{y} or similar materials.

The p-contact layer (209) and the p-contact (112) are etched to form an optical aperture (232). Light generated in the active region comes out (223) through the optical aperture (232). A major shortcoming of conventional light-emitting diodes is that a large part of generated optical power is lost. Part of the generated light is directed into the substrate (221) and is absorbed in the metal contact (111). Another part of the generated light is directed at an angle exceeding the angle of the total internal reflection at the semiconductor/air boundary and is reflected back (222). This light also comes into the substrate and is absorbed in the contact. Only part of the generated light comes out (223). Another disadvantage is poor wavelength stabilization of conventional LEDs. Changing the drive current results in a change of the emission spectrum color. Because of this disadvantage, a wavelength stabilization is needed, which would improve light extraction in a certain spectral range.

Therefore, there is a need for both a semiconductor diode laser and a light-emitting diode that overcomes the shortcomings of the prior art.

### SUMMARY OF THE INVENTION

A novel class of semiconductor light-emitting devices, or “tilted cavity light-emitting devices” is disclosed. The device includes at least one active element with an active region generating an optical gain by injection of a current and two mirrors. The active element is generally placed within a cavity. The cavity and the mirrors are optimized such that the device generates optical modes that propagate in directions, which are tilted with respect to both the p-n junction plane and the direction normal to this plane. A wavelength-selective tilted cavity light-emitting diode is also disclosed, where the cavity and the mirrors are designed such that transmission of generated optical power within a certain spectral range and within a certain interval of angles to the substrate is minimized. Transmission of optical power within a certain spectral range, which corresponds to the emission range of the light-emitting active medium and within a certain interval of angles out of the device, is optimized to achieve a required output power level.

A wavelength-stabilized tilted cavity semiconductor diode laser operating in the edge-emitting geometry is disclosed, which includes at least one high-finesse cavity and at least one multilayered interference reflector serving as a mirror, where the average refractive index of the high-finesse cavity differs from the average refractive index of the multilayered interference reflector by at least 2%. The high-finesse cavity and the multilayered interference reflector are designed such that the reflectivity dip of the cavity and the reflectivity maximum of the mirror coincide at one tilt angle and one wavelength and diverge as the wavelength changes. This results in wavelength-selective leaky losses of the tilted optical mode to the substrate or contact layers, and thus, results in wavelength-stabilized lasing.

### BRIEF DESCRIPTION OF THE DRAWINGS

FIG. 1(a) shows a conventional prior art edge-emitting laser.

FIG. 1(b) shows a conventional prior art vertical cavity surface-emitting laser with doped mirrors.

FIG. 2 shows a conventional prior art light-emitting diode.

FIG. 3 shows prior art reflectivity spectra of a multilayered periodic structure at different angles of incidence.

FIG. 4 shows a schematic diagram of a tilted cavity laser embodiment of the present invention.

FIG. 5(a) shows a first embodiment of a light-emitting diode of the present invention.

FIG. 5(b) shows the active region of the embodiment of FIG. 5(a) showing that tilted optical modes at different tilt angles are present in the emitted light.

FIG. 6 shows a second embodiment of a light-emitting diode of the present invention.

FIG. 7 shows a third embodiment of the light-emitting diode of the present invention.

FIG. 8 shows a fourth embodiment of a light-emitting diode of the present invention.

FIG. 9 shows an embodiment of a light-emitting system of the present invention.

FIG. 10 shows a first embodiment of a tilted cavity laser of the present invention.

FIG. 11 shows a second embodiment of a tilted cavity laser of the present invention.

FIG. 12 shows a third embodiment of a tilted cavity laser of the present invention.

FIG. 13(a) shows schematically a tilted optical mode in a model waveguide comprising two metal surfaces bounding a layer of air.

FIG. 13(b) shows schematically a profile of aluminum composition and a tilted optical mode which propagates at an effective angle tilted 17.3 degrees to the direction normal to the p-n junction plane.

FIG. 13(c) shows schematically the Fourier power spectrum of the tilted mode of FIG. 13(b).

FIG. 14(a) shows the reflectivity spectrum of a high-finesse cavity at three different angles of incidence showing a strong shift of the cavity dip with the angle.

FIG. 14(b) shows the reflectivity spectrum of a multilayered interference reflector at three different angles of incidence showing a weak shift of the stopband maximum with the angle.

FIG. 14(c) shows a high-finesse cavity in an embodiment of the present invention.

FIG. 14(d) shows a multilayered interference reflector in an embodiment of the present invention.

FIG. 14(e) shows a waveguide of a tilted cavity laser of the present invention.

FIG. 15(a) shows a larger magnification of the high-finesse cavity shown in FIG. 14(c).

FIG. 15(b) shows the reflectivity spectrum of the high-finesse cavity of FIG. 15(a) at three different angles of incidence.

FIG. 16(a) shows the multilayered interference reflector (MIR) of FIG. 14(d) at a larger magnification.

FIG. 16(b) shows the reflectivity spectrum of the multilayered interference reflector of FIG. 16(a).

FIG. 17(a) shows the structure of FIG. 14(e), including a high-finesse cavity and a multilayered interference reflector, at a larger magnification.

FIG. 17(b) shows a structure, including a high-finesse cavity sandwiched between two multilayered interference reflectors.

FIG. 18(a) shows a multilayered interference reflector including two high-finesse cavities having spectral positions of the reflectivity dips at different wavelengths.

FIG. 18(b) shows the reflectivity spectrum of the multilayered interference reflector of FIG. 18(a), depicting two dips at different wavelengths.

FIG. 18(c) shows a multilayered interference reflector constructed by n times periodic repetition of a four-layered element of FIG. 18(a) including two cavities.

FIG. 18(d) shows the reflectivity spectrum of the multilayered interference reflector of FIG. 18(c) for the particular case n=5.

FIG. 19(a) shows the reflectivity spectrum of the multilayered interference reflector of FIG. 18(c), where the thickness of the low-index layers is 400 nm.

FIG. 19(b) shows the reflectivity spectrum of the multilayered interference reflector of FIG. 18(c), where the thickness of the low-index layers is 300 nm.

FIG. 19(c) shows the reflectivity spectrum of the multilayered interference reflector of FIG. 18(c), where the thickness of the low-index layers is 200 nm.

FIG. 20(a) shows the reflectivity spectrum of the periodic multilayered interference reflector of FIG. 18(c) including 15 periods, where the thickness of low-index layers is 140 nm.

FIG. 20(b) shows the reflectivity spectrum of the periodic multilayered interference reflector of FIG. 18(c) including 15 periods, where the thickness of low-index layers is 130 nm.

FIG. 20(c) shows the reflectivity spectrum of the periodic multilayered interference reflector of FIG. 18(c) including 15 periods, where the thickness of low-index layers is 120 nm.

FIG. 21 shows the central spikes of the spectra of FIG. 20(a) through FIG. 20(c) at a larger magnification.

FIG. 22(a) shows schematically the model structure of a tilted cavity laser used in the calculation of the tilted optical modes by applying the method of perfectly matched layers.

FIG. 22(b) shows schematically the spatial profile of a few optical modes of a tilted cavity laser optimized to emit at the resonant wavelength 980 nm.

FIG. 23 shows the spatial profile of the resonant optical mode of a tilted cavity laser, as in FIG. 22(b), but at a wavelength of 965 nm, far from the resonant wavelength at a larger magnification.

FIG. 24 shows the spatial profile of the resonant optical mode of a tilted cavity laser, as in FIG. 22(b), at the resonant wavelength of 980 nm at a larger magnification.

FIG. 25 shows the spatial profile of the resonant optical mode of a tilted cavity laser, as in FIG. 22(b), but at a wavelength of 990 nm, far from the resonant wavelength at a larger magnification.

FIG. 26 shows the spectrum of leaky losses of a tilted cavity laser, designed for the wavelength of 1290 nm, at two different temperatures, 27° C. and 127° C. revealing a shift of the resonant wavelength by 25 nm for the temperature shift of 100° C.

FIG. 27(a) shows a tilted cavity laser including a low-refractive index MIR, in which the most remote layer of the MIR has a thickness smaller than the other layers of the MIR with the low refractive index.

FIG. 27(b) shows a tilted cavity laser including a high-refractive index MIR, in which the layer closest to the cavity of the MIR has a thickness lower than the other layers of the MIR with a high refractive index.

FIG. 28(a) shows the spatial profile of the resonant optical mode of a tilted cavity laser of the present invention.

FIG. 28(b) shows the aluminum composition in the semiconductor part of the structure of a tilted cavity laser of the present invention.

FIG. 28(c) shows a fourth embodiment of a tilted cavity laser of the present invention.

FIG. 29 shows a fifth embodiment of a tilted cavity laser of the present invention.

FIG. 30 shows a sixth embodiment of a tilted cavity laser of the present invention.

FIG. 31 shows a seventh embodiment of a tilted cavity laser of the present invention.

FIG. 32 shows an embodiment of a tilted cavity two-section mode-locked laser of the present invention.

FIG. 33 shows a first embodiment of a tilted cavity mode-locked laser of the present invention.

FIG. 34 shows a second embodiment of a tilted cavity mode-locked laser of the present invention.

FIG. 35 shows a third embodiment of a tilted cavity mode-locked laser of the present invention.

FIG. 36 shows a fourth embodiment of a tilted cavity mode-locked laser of the present invention.

FIG. 37 shows schematically a top view of a tilted cavity laser, in which the stripe forming the top contact is rotated such that it forms an angle with the facets that is not 90 degrees.

FIG. 38 shows schematically a tilted cavity optical amplifier in an embodiment of the present invention.

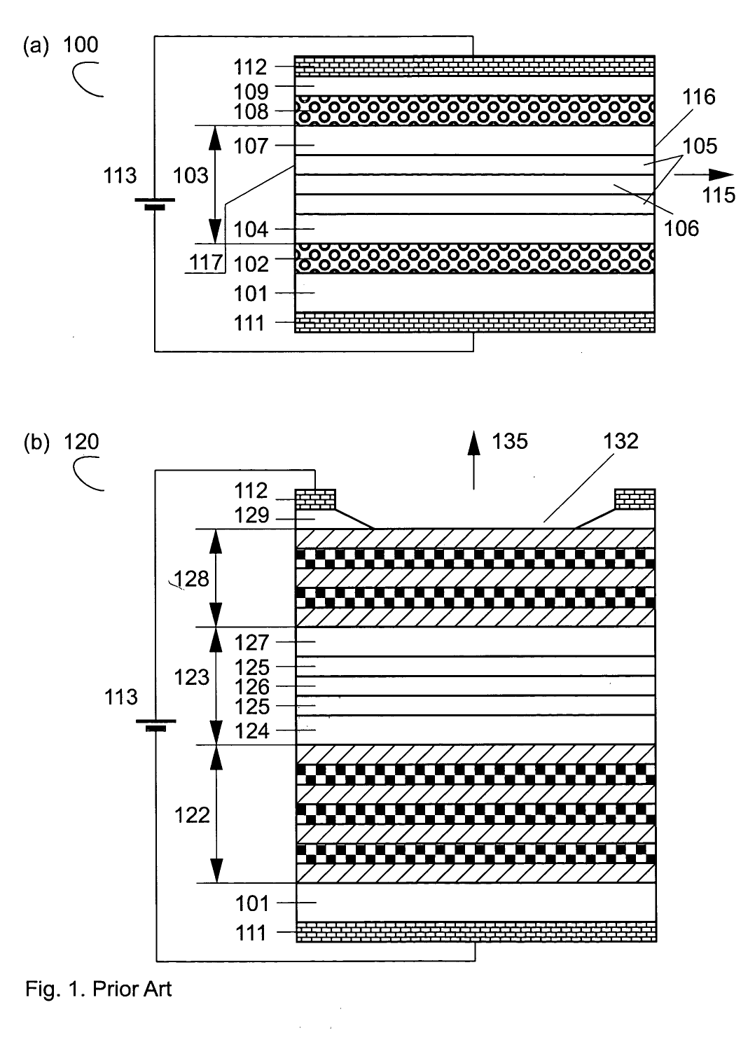

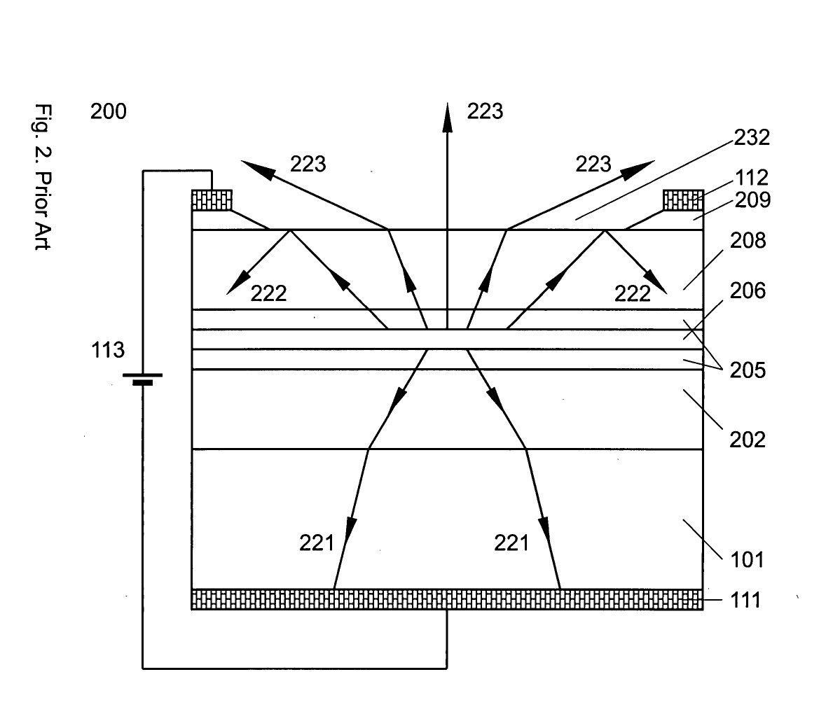

### DETAILED DESCRIPTION OF THE INVENTION

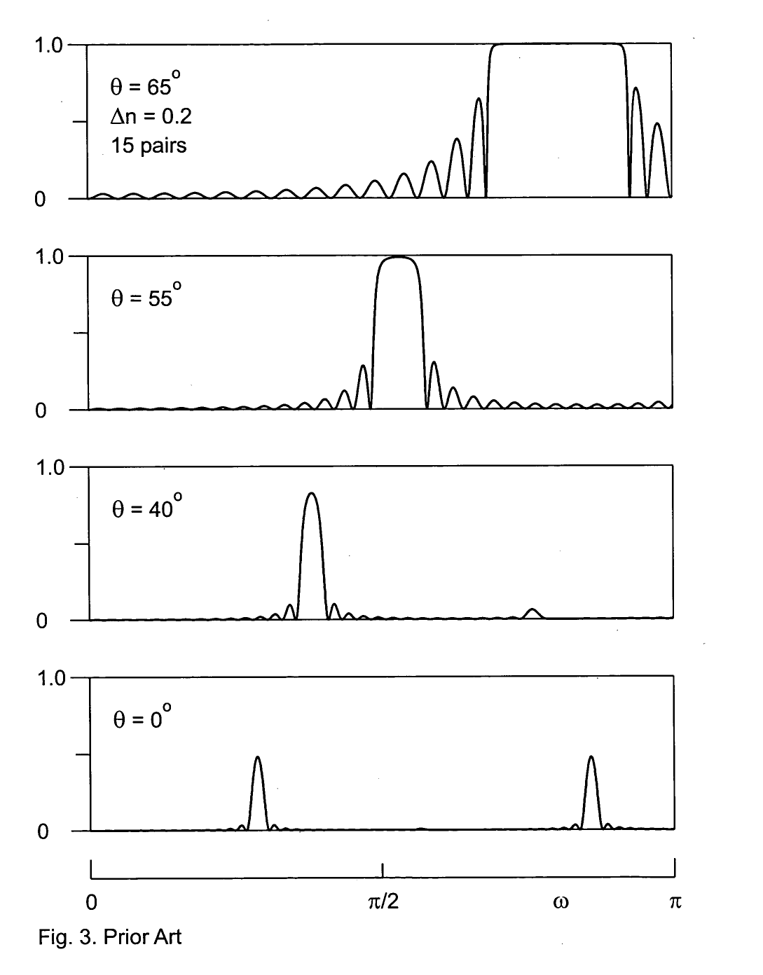

A way to overcome the shortcomings of both semiconductor diode lasers, switches, optical amplifiers, photodetectors, on the one hand, and light-emitting diodes, on the other hand, is related to the concept of a tilted cavity light-emitting device. This concept is based on the fundamental physical properties of multilayered structures, i.e, on the laws of propagation, transmission, and reflection of electromagnetic waves at oblique incidence. FIG. 3 illustrates the reflectivity spectrum of a periodic multilayered structure for a few different tilt angles of the propagating TE electromagnetic wave, as described by A. Yariv and P. Yeh, in Optical Waves in Crystals. Propagation and Control of Laser Radiation, Wiley, 1984. Light comes from the medium with a refractive index n₁=3.6, and the structure includes 15 periods, each period further including one layer of the Λ/2 thickness having a low refractive index n₂=3.4 and one layer of equal Λ/2 thickness having a high refractive index n₁=3.6. The reflectivity is plotted as a function of the frequency ω of the electromagnetic wave, and ω is measured in units of c/Λ, where c is the speed of light in a vacuum.

The major properties illustrated in FIG. 3 are as follows. At the normal incidence, θ=0, the reflectivity spectrum reveals narrow spikes of a low amplitude. As the angle θ increases, spikes shift towards higher frequencies, and hence, shorter wavelengths, the amplitude of the spikes increases, and the spikes become broader, forming stopbands with a reflectivity close to 1. This property of a strong dependence of the reflectivity of electromagnetic waves from a multilayered structure on the angle of incidence is the basis of the concept of a tilted cavity semiconductor diode laser. This laser was disclosed in a co-pending U.S. Patent Application Publication No. 2003/0152120 by Ledentsov et al., herein incorporated by reference. In the tilted cavity laser, light propagates at an angle with respect to multilayer interference mirrors (MIRs), and the MIRs and the cavity are optimized for tilted photon propagation.

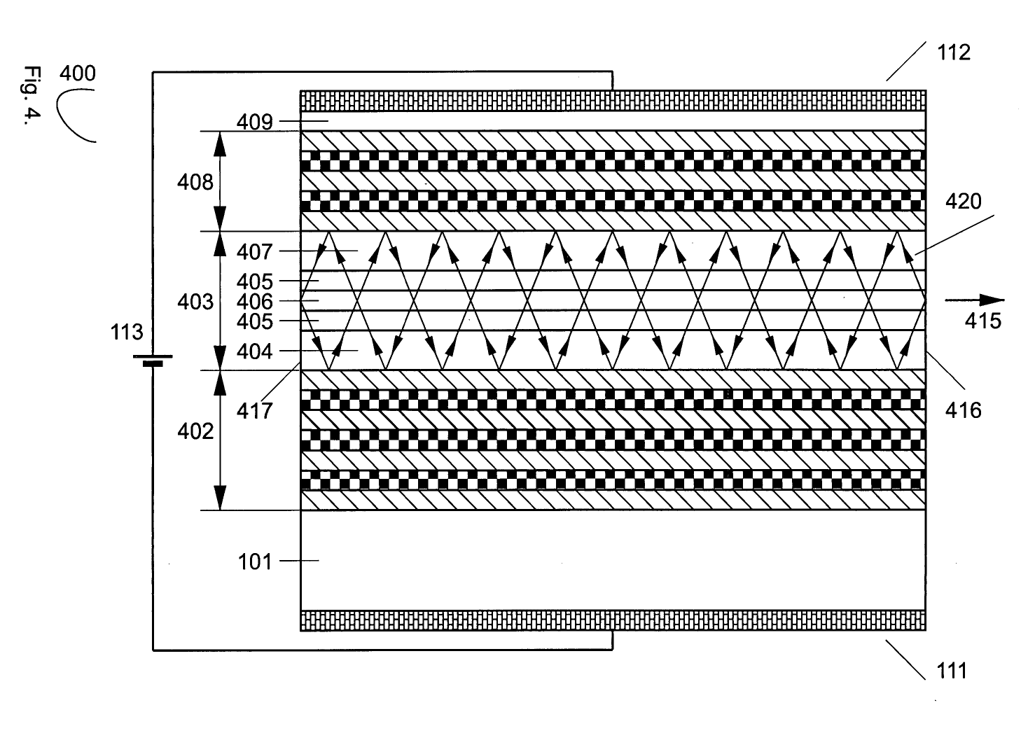

The tilted cavity laser (400) shown in FIG. 4 is grown epitaxially on an n-doped substrate (101) and includes an n-doped bottom multilayered interference reflector (MIR) (402), a cavity (403), a p-doped top multilayered interference reflector (408), and a p-contact layer (409). The cavity (403) includes an n-doped layer (404), a confinement layer (405), and a p-doped layer (407). The confinement layer (405) further includes an active region (406). The laser structure (400) is bounded in the lateral plane by a rear facet (417) and a front facet (416). The cavity (403) and the multilayered interference reflectors (402) and (407) are designed such that resonant conditions for the cavity and for multilayered interference reflectors are met for only one tilted optical mode (420), the light propagating at a certain tilt angle and having a certain wavelength. If the rear facet (417) is covered by a highly reflecting coating, the output laser light (415) comes out only through the front facet (416). The advantage of this design of a tilted cavity laser is that wavelength stabilization and a high output power are obtained at the same time. Since the cavity (403), together with the bottom MIR (402) and the top MIR (408) are designed such that lasing occurs in a tilted optical mode, the cavity (403) is termed “tilted cavity” herein.

The layers forming the bottom multilayered interference reflector (402) are formed from materials lattice-matched or nearly lattice matched to the substrate (101), are transparent to the generated light, are doped by a donor impurity and have alternating high and low refractive indices. For a tilted cavity laser grown on a GaAs substrate, alternating layers of GaAs and GaAlAs or layers of GaAlAs having alternating aluminum content preferably form the mirror.

The n-doped layer (404) of the cavity (403) is formed from a material lattice-matched or nearly lattice-matched to the substrate (101), is transparent to the generated light, and is doped by a donor impurity.

The p-doped layer (407) of the cavity (403) is formed from a material lattice-matched or nearly lattice-matched to the substrate (101), is transparent to the generated light, and is doped by an acceptor impurity.

The layers forming the top multilayered interference reflector (408) are formed from materials lattice-matched or nearly lattice-matched to the substrate (101), are transparent to the generated light, are doped by an acceptor impurity, and have alternating high and low refractive indices. For a tilted cavity laser grown on a GaAs substrate, alternating layers of GaAs and GaAlAs or layers of GaAlAs having alternating aluminum content form the mirror.

The p-contact layer (409) is formed from a material doped by an acceptor impurity. For a tilted cavity laser grown on a GaAs substrate, the preferred material is GaAs. The doping level is preferably higher than that in the top multilayered interference reflector (408).

The confinement layer (405) is formed from a material lattice-matched or nearly lattice-matched to the substrate (101), is transparent to the generated light, and is either undoped or weakly doped. The confinement layers are preferably formed from the same material as the substrate (101).

The active region (406) placed within the confinement layer (405) is preferably formed by any insertion, the energy band gap of which is narrower than that of the substrate (101). Possible active regions (406) include, but are not limited to, a single-layer or a multi-layer system of quantum wells, quantum wires, quantum dots, or any combination thereof. In the case of a device on a GaAs-substrate, examples of the active region (406) include, but are not limited to, a system of insertions of InAs, In₁₋ₓGaₓAs, InₓGa_{1-x-y}Al_{y}As, InₓGa₁₋ₓAs_{1-y}N_{y} or similar materials.

The present invention extends the concept of using tilted cavity optical modes to light-emitting diodes. Also, the wavelength selectivity of the lasers is enhanced.

Effective Angle of Optical Modes

In most of the embodiments of the present invention, a tilted cavity optoelectronic device includes a multilayered structure, in which a refractive index is modulated in the direction perpendicular to the p-n junction plane. The coordinate reference frame is hereby defined such that the p-n junction plane is the (xy) plane. The refractive index n is modulated in the z-direction, n=n(z). Then, in any optical mode, the temporal and spatial behavior of the electric (E) and magnetic (H) fields is written as follows,
\tilde{E}ᵢ(x,y,z;t)=Re[exp(−iωt)exp(iβₓx+iβ_{y}y)Eᵢ(z)], (1a)
\tilde{H}ᵢ(x,y,z;t)=Re[exp(−iωt)exp(iβₓx+iβ_{y}y)Hᵢ(z)], (1b)
where ω is the frequency of light, βₓ and β_{y} are propagation constants, Re stands for the real part of a complex number, and the index i=x,y,z. Let the axes x and y be defined such that the propagation constants are
βₓ=β and β_{y}=0. (2)
Then, for TE optical modes the Maxwell's equations reduce to a scalar equation for the only non-zero component of the electric field, E_{y}(z),

$$- \frac{{ⅆ}^{2}}{ⅆ {z}^{2}} {E}_{y} ( z ) + {β}^{2} {E}_{y} ( z ) = {n}^{2} ( z ) \frac{{ω}^{2}}{{c}^{2}} {E}_{y} ( z ) , \qquad ( 3 )$$

as shown previously by H. C. Casey, Jr. and M. B. Panish in Heterostructure Lasers Part A, Academic Press, New York, 1978, pp. 34-57. Most practical structures used in optoelectronic devices are layered structures where the refractive index within each i-th layer is constant, and
n(z)=nᵢ. (4)
Then the solution of Eq. (3) within the i-th layer may be written as a linear combination of two waves,
E_{y}(z)=A exp(iqᵢz)+B exp(−iqᵢz), (5a)
where

$${q}_{1} = \sqrt{{n}_{i}^{2} \frac{{ω}^{2}}{{c}^{2}} - {β}^{2}} , if {n}_{i} \frac{ω}{c} > β , \qquad ( 5 b )$$

or
E_{y}(z)=C exp(kᵢz)+D exp(−kᵢz), (6a)
where

$${κ}_{i} = \sqrt{{β}^{2} - {n}_{i}^{2} \frac{{ω}^{2}}{{c}^{2}}} , if {n}_{i} \frac{ω}{c} < β . \qquad ( 6 b )$$

In the case of Eq. (5b), if the electric field within the i-th layer is a standing wave, which is a combination of two traveling waves, each of the traveling waves within this particular i-th layer propagates at an angle θ or −θ with respect to the axis z, where

$$ϑ = {tan}^{- 1} \frac{β}{{q}_{i}} . \qquad ( 7 )$$

In the case of Eq. (6b), the electric field within the i-th layer is the combination of increasing and decreasing exponentials, and it is not possible to define an angle.

FIG. 3 shows that the optical properties, e.g. the reflection or transmission coefficients of any multilayered structure depend dramatically on the angle of incidence of the electromagnetic wave. This property of multilayered structures is employed in all embodiments of the present invention. Therefore, it is convenient to characterize any optical mode by its angle of propagation. When the angle is defined in accordance with Eq. (7), the angle is different for different layers. From hereto forward the following conventions are used. One layer is fixed as the reference layer, and its refractive index is denoted as n₀. It is convenient to choose for this layer a layer with a high refractive index, preferably the layer having the maximum refractive index nₘₐₓ or a layer having a refractive index close to the maximum refractive index. For example, in a multilayered structure including layers of GaAs and Ga₁₋ₓAlₓAs, it is convenient to choose a layer of GaAs as the reference layer. All layers of Ga₁₋ₓAlₓAs typically have refractive indices lower than the reference layer of GaAs, and the optical modes have propagation constants that obey the relationship

$$β < {n}_{max} \frac{ω}{c} = {n}_{0} \frac{ω}{c} , \qquad ( 8 )$$

and the electric field of the optical modes within the reference layer are a combination of traveling waves according to Eq. (5a). Thus, it is possible to define the angle of propagation within the layer of GaAs, according to Eq. (7).

If InAs or GaInAs layers, for example, in quantum well or quantum dot layers, are present in the structure, their refractive indices may be higher than that of GaAs. However, their thickness is typically very small, and these layers do not make a dramatic impact on the propagation constants β of the optical modes, and the relationship

$$β < {n}_{0} \frac{ω}{c} , \qquad ( 9 )$$

is still valid for the optical modes. Thus, in what follows, every optical mode is assigned an angle θ, according to

$$ϑ = {tan}^{- 1} \frac{β}{\sqrt{{n}_{0}^{2} \frac{{ω}^{2}}{{c}^{2}} - {β}^{2}}} , \qquad ( 10 )$$

where n₀ is the refractive index of the reference layer. For GaAs-based optoelectronic devices, a GaAs layer is chosen as the reference layer. It should be noted that it is possible to choose a layer as the reference layer even in the case where such a layer is not present in the structure and all layers present have refractive indices lower than that of the reference layer. For example, if the structure includes the layers of Ga₁₋ₓAlₓAs with different values of aluminum composition x, and no layer of GaAs is present in the structure, it is still possible to choose a layer of GaAs as the reference layer in order to define the angle θ.

The major advantage of describing the optical modes by an angle θ relates to the following. When a complete layered structure of the optoelectronic device is considered, the optical modes are found from the solution of Eq. (3). Then each optical mode has its propagation constant β and the corresponding angle of propagation θ defined according to Eq. (10). In this case describing the optical modes by their propagation constants or by the angles is equivalent.

A striking difference arises when optical properties of a single element of a device, and not of the whole device, are considered. Then the optical modes are not defined for a single element. However, optical properties of a single element are described, if one considers the reflectivity spectrum of this element at a certain angle of incidence. For example, a method is described below for constructing a tilted cavity laser including at least one cavity and at least one multilayered interference reflector (MIR). The cavity and the MIR are designed such that the cavity has a narrow dip in the reflectivity spectrum, and the MIR has a stopband in the reflectivity spectrum, and at a certain optimum tilt angle, the cavity dip and the maximum stopband reflectivity coincide at a certain wavelength. As the tilt angle deviates from the optimum angle, the cavity dip and the maximum stopband reflectivity draw apart. Such an approach ensures the selectivity of the leaky losses and provides wavelength-stabilized operation of the laser.

It is important to specify certain terminology. For a given optical mode characterized by a tilt angle θ, the electric field in other layers are either oscillating, as in Eq. (5a), or is a linear combination of exponentially increasing and exponentially decreasing exponents, as in Eq. (6a). This allows terminology to be specified for mirrors or reflectors. If a mirror includes one or a plurality of layers, in each of which the electric field of the given optical mode is a linear combination of exponentially increasing and exponentially decreasing exponents, similar to Eq. (6a), this mirror is designated a total internal reflector, or an evanescent reflector. If a mirror includes one or a plurality of layers, and in at least one of the layers the electric field of a given optical mode exhibits an oscillatory behavior according to Eq. (5a), this mirror is designated an interference reflector. As most of the embodiments include a reflector with a plurality of layers, the present invention deals mostly with a multilayered interference reflector (MIR). It should be noted that the same single-layered or multi-layered structure is either an evanescent reflector or an interference reflector depending on the optical mode.

Tilted Cavity Light-Emitting Diodes

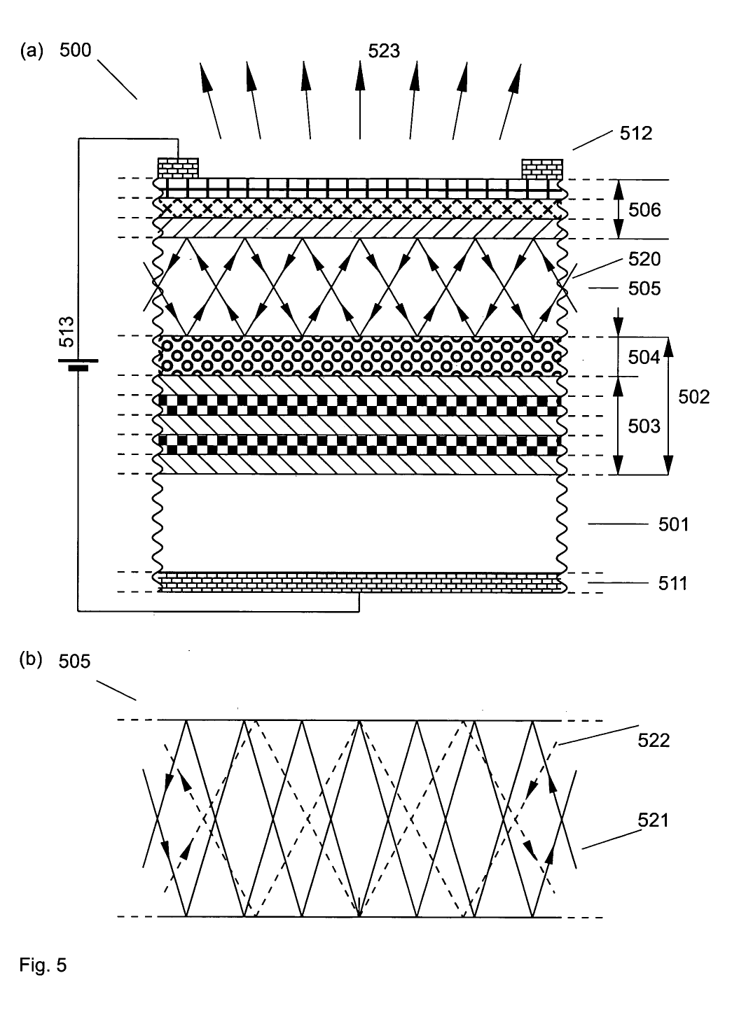

FIG. 5(a) shows a schematic diagram of a wavelength-selective tilted cavity light-emitting diode according to an embodiment of the present invention. The light-emitting diode (500) is grown epitaxially on an n-doped substrate (501) and includes an n-doped bottom mirror (502), an active region (505), and a p-doped multilayered top coating (506). The active region (505) emits light when a forward bias (513) is applied. The multilayered bottom mirror (502) is designed such that it reflects light in the maximum possible spectral range within the spectral range of emitted light and in the maximum possible interval of angles. In this particular embodiment, the multilayered bottom mirror (502) is shown to include two sections (503) and (504). The multilayered interference reflector section (503) of the bottom mirror (502) is designed such that it efficiently reflects optical modes propagating close to the direction normal to the p-n junction plane. The total internal reflector or evanescent reflector section (504) of the bottom mirror (502) is designed such that it efficiently reflects optical modes propagating at large tilt angles. In general, the bottom mirror (502) is optimized preferably such that it reflects back the maximum optical power generated in the active region. The multilayered top coating (506) is designed such that it is antireflecting for a wide range of angles and a wide spectral range within the spectrum of generated by the active region. The multilayered top coating is optimized not for a maximum transmission coefficient for the normal incidence, but is preferably optimized to provide the maximum averaged transmitted power in a range of angles from 0 to the angle of the total internal reflection at the semiconductor/air interface.

The n-contact (511) is preferably mounted on the bottom side of the n-doped substrate (501). The p-contact (512) is preferably mounted on top of the multilayered top coating (506). The bias (513) is applied to the active region (505) through the n-contact (511) and the p-contact (512). Light comes out (523) through the top multilayered coating.

FIG. 5(b) shows the active region (505) at a larger magnification, illustrating that a plurality of tilted optical modes in a certain range of angles is generated. Two modes (521) and (522) are shown as an example.

In another embodiment of the present invention, a wavelength-selective tilted cavity light-emitting diode can operate as a superluminescent light-emitting diode, if the drive current is sufficient to provide optical gain.

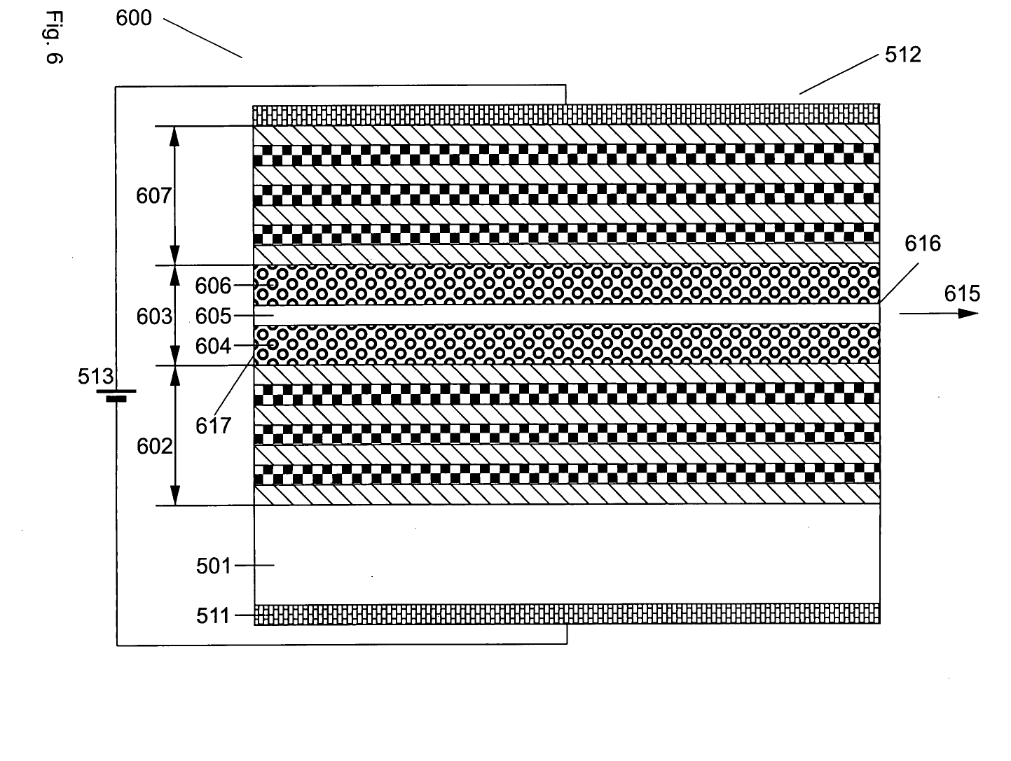

FIG. 6 shows a schematic diagram of a light-emitting diode in another embodiment of the present invention. The light-emitting diode (600) is grown epitaxially on an n-doped substrate (501) and includes an n-doped bottom multilayered interference reflector (602), an antiwaveguide (603), and a p-doped top multilayered interference reflector (607). The antiwaveguide (603) further includes an n-doped layer (604), an active region (605), and a p-doped layer (606). The layers (604) and (606), including the antiwaveguide (603), preferably have a low refractive index such that only one mode overlaps with the active region (605), while none of the other transverse optical modes overlap with the active region (605). Then, all generated light is generated in a single transverse optical mode. If the rear facet (617) of the structure is covered by a highly reflecting coating, all generated light comes out (615) through the front facet (616), and light has a well-defined far-field profile, the latter being determined by the active vertical optical mode. Preferably, the particular criterion that the section (603), discussed in FIG. 6 as including three layers, acts as an antiwaveguide is written in terms of the average refractive indices:
n_{antiwaveguide}<n_{MIR}. (11)
The particular definition of the average refractive index of the MIR depends on the propagation angle of the optical mode in question. As an estimate, one may define the average refractive index of an MIR as a square root of the weighted averaged square of the refractive index. Thus, for an MIR including a periodic structure, where each period further includes a first layer of a thickness d₁ and a refractive index n₁ and a second layer of a thickness d₂ and a refractive index n₂, the effective refractive index of the MIR is approximated as

$${n}_{MIR} = \sqrt{\frac{{n}_{1}^{2} {d}_{1} + {n}_{2}^{2} {d}_{2}}{{d}_{1} + {d}_{2}}} . \qquad ( 12 )$$

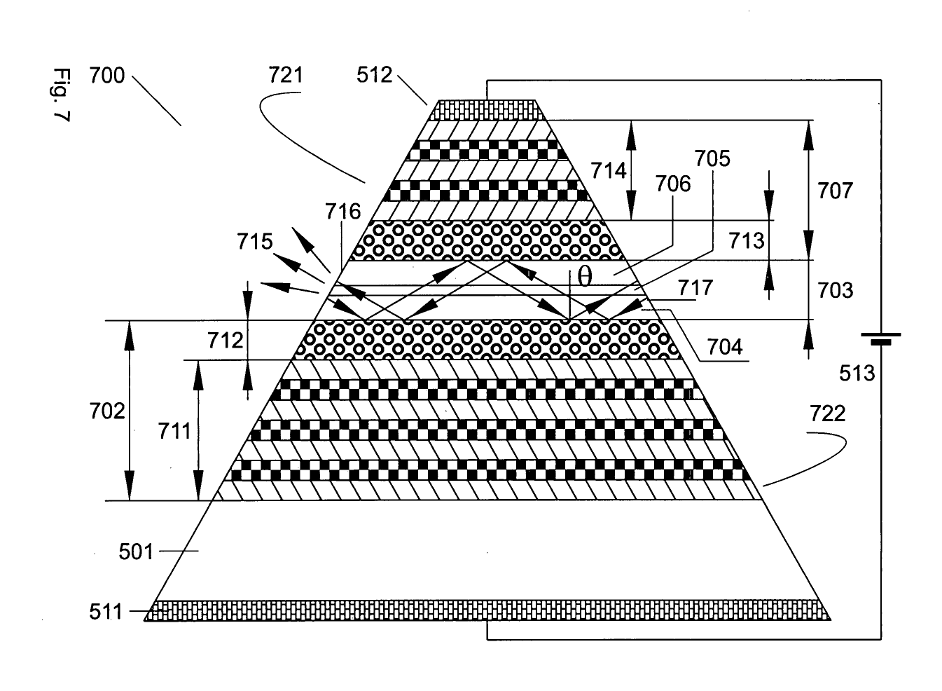

FIG. 7 shows a schematic diagram of a light-emitting diode in another embodiment of the present invention. The light-emitting diode (700) is grown epitaxially on an n-doped substrate (501). The structure includes an n-doped bottom mirror (702), a cavity (703), and a p-doped top mirror (707). The bottom mirror (702) further includes a multilayered interference reflector (711) and a total internal reflector (712). The cavity (703) further includes an n-doped layer (704), an active region (705), and a p-doped layer (706). The top mirror (707) further includes a total internal reflector (713) and a multilayered interference reflector (714). The epitaxially grown structure is etched such that the front facet (721) and the rear facet (722) are tilted with respect to the substrate plane at a certain angle, and the cross-section of the structure has the shape of a trapezoid. The bottom mirror (702) and the top mirror (707) are preferably optimized such that they reflect the maximum optical power back to the cavity (703). A major advantage of a structure with tilted rear (722) and front facets (721) is that in tilted optical modes generated light in the active region approaches the front facet (721) in close to a normal direction. Then light in all optical modes, for which the angle of incidence at the front facet is lower than the angle of total internal reflectance at the semiconductor-air interface, efficiently comes out (715). If the rear facet (722) is covered by a highly reflecting coating, light comes out (715) only through the front facet (721). In a preferred embodiment, the front facet is coated by an antireflecting coating, and the rear facet is coated by a highly reflecting coating.

In another embodiment of the present invention, the structure of a tilted cavity LED shown schematically in FIG. 7, is optimized such that the resonant optical mode impinges to the front facet at a Brewster angle, at which the reflectivity for TM optical modes vanishes.

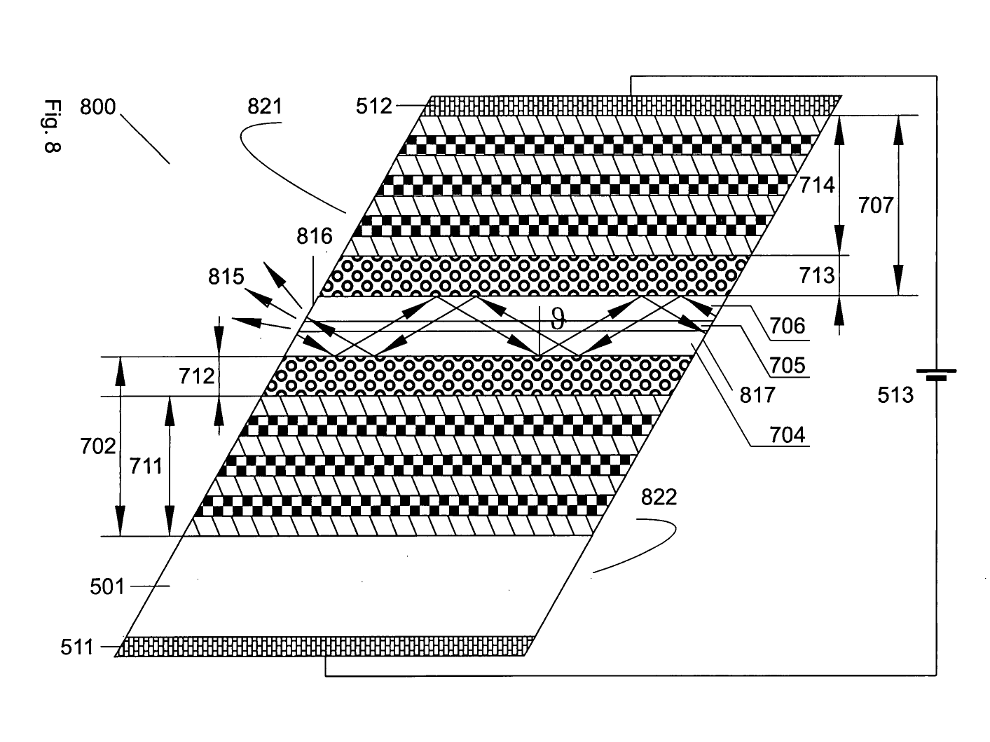

FIG. 8 shows a schematic diagram of a light-emitting diode of another embodiment of the present invention. The epitaxially grown structure (800) is etched such that the front facet (821) and the rear facet (822) are tilted with respect to the substrate plane at a certain angle, and the cross-section of the structure has the shape of a parallelogram. Light is generated in tilted optical modes propagating in a certain range of angles, and this light approaches the front facet (821) at a normal direction or at a small angle below the angle of total internal reflection at the semiconductor-air interface, which allows efficient transmission of light into air. If the rear facet (822) is covered by a highly reflecting coating, light comes out (815) only through the front facet (821).

In another embodiment of the present invention, the structure of a tilted cavity LED shown schematically in FIG. 8 is optimized such that the resonant optical mode impinges to the front facet at a Brewster angle, at which the reflectivity for TM optical modes vanishes.

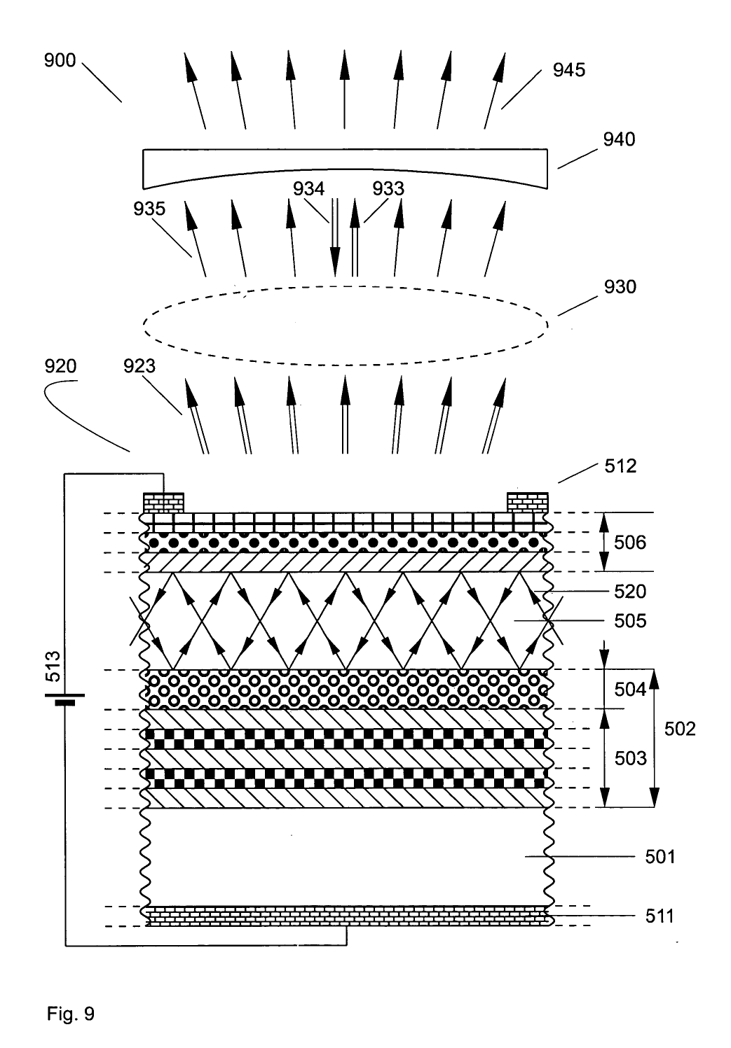

FIG. 9 shows a schematic diagram of a light-emitting system of another embodiment of the present invention. The light-emitting system (900) includes a light-emitting diode (920), a phosphorus-containing medium (930), and an external mirror (940). The light-emitting diode (920) is preferably constructed according to the embodiment shown in FIG. 5. Light present within the light-emitting diode (920) as a plurality of tilted optical modes (520), comes (923) through the top coating (506). Light (923) is in the ultraviolet spectral region. Ultraviolet light (923) comes through the phosphorus-containing medium (930), and light is partially absorbed in the phosphorus-containing medium. Due to photoluminescence from the excited phosphorus-containing medium (930), visible light (935) and some ultraviolet light (940) is generated. The visible light (935) and ultraviolet light (933) approach the mirror (940). The mirror (940) is semi-transparent to visible light and non-transparent to ultraviolet light, which is reflected back (934). Transmitted visible light (945) comes out of the light-emitting system.

Tilted Cavity Optoelectronic Device with Tilted Facets

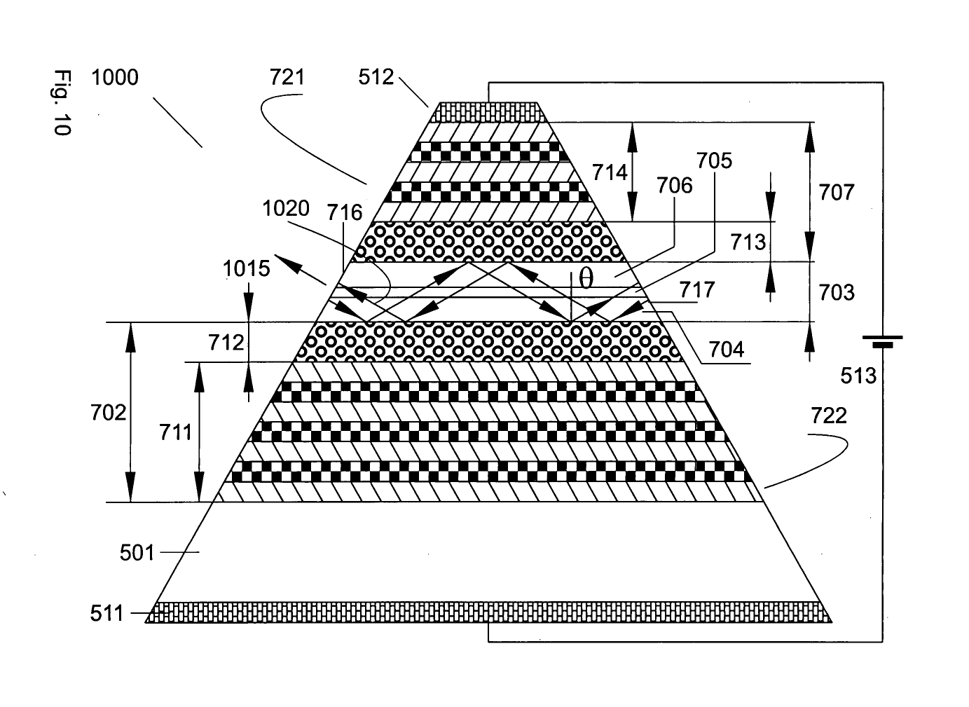

FIG. 10 shows a schematic diagram of a tilted cavity laser in another embodiment of the present invention. The tilted cavity laser (1000) is grown epitaxially on a substrate, and front and rear facets of the epitaxial structure are etched at tilt angles with respect to the substrate so that the cross section has a shape of a trapezoid, similar to the structure of the light-emitting diode depicted in FIG. 7. The active region (705), the bottom mirror (702), and the top mirror (707) of the tilted cavity laser are designed such that the lasing conditions are met for a tilted optical mode (1020). The wavelength selectivity of the lasing is further enhanced by the fact that positive feedback exists for only one tilted optical mode, for which generated light propagates normally to the front facet (716) and the rear facet (717). If the rear facet (717) is covered by a highly reflecting coating, the laser light comes out (1015) through the front facet (716) only.

Another embodiment of the present invention is a tilted cavity optical amplifier designed to have tilted facets, similar to FIG. 10, such that the light in a resonant optical mode impinges on a front facet at a Brewster angle, at which the reflectivity of TM modes vanishes.

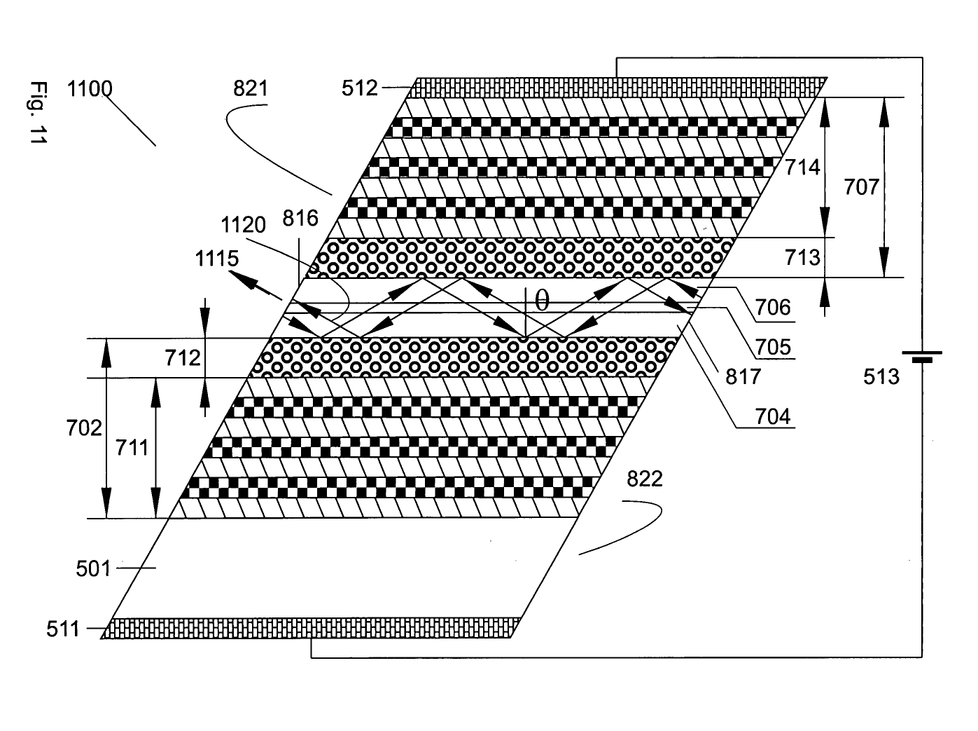

FIG. 11 shows a schematic diagram of a tilted cavity laser in another embodiment of the present invention. The tilted cavity laser (1100) is grown epitaxially on a substrate, and front and rear facets of the epitaxial structure are etched at tilt angles with respect to the substrate so that the cross section has the shape of a parallelogram, similar to the structure of the light-emitting diode depicted in FIG. 8. The active region (705), the bottom mirror (702), and the top mirror (707) of the tilted cavity laser are designed such that the lasing conditions are met for a tilted optical mode (1120). The wavelength selectivity of the lasing is further enhanced by the fact that positive feedback exists for only one tilted optical mode, for which generated light propagates normally to the front facet (816) and the rear facet (817). If the rear facet (817) is covered by a highly reflecting coating, the laser light comes out (1115) through the front facet (816) only.

In another embodiment of the present invention, a tilted cavity optical amplifier is designed to have tilted facets, similar to FIG. 11, such that the light in a resonant optical mode impinges on a front facet at a Brewster angle, at which the reflectivity of TM modes vanishes.

Tilted Cavity Laser with an External Mirror

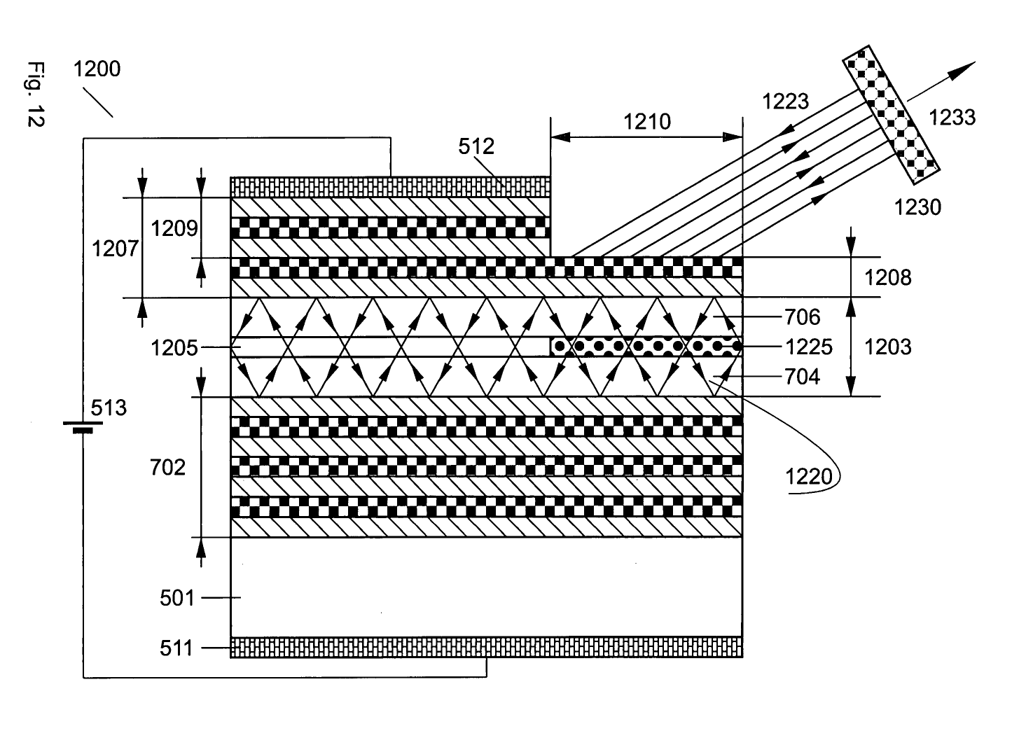

FIG. 12 shows a schematic diagram of a tilted cavity laser of another embodiment of the present invention, where the selectivity of lasing wavelength is further enhanced by use of an external mirror. The tilted cavity laser (1200) is grown epitaxially on an n-doped substrate (501) and includes an n-doped bottom mirror (702), a cavity (1203), and a p-doped top mirror (1207). Multilayered interference reflectors are used for the bottom mirror (702) and for the top mirror (1207). Part (1208) of the top mirror (1207) persists over the entire device structure, and a part (1209) of the top mirror is partially etched away. A tilted optical mode (1220) is generated by the active region (1205). The tilted cavity laser is designed such that the tilt angle of the resonant tilted optical mode is below the angle of total internal reflectance at the semiconductor-air interface, and light comes out from the etched part (1210) of the top mirror. The active layer (1205), the bottom mirror (702), and the top (1207) mirror are designed such that positive feedback for all optical modes generated by the active layer (1205) is not sufficient for lasing. An external semitransparent mirror (1230) provides additional positive feedback for one and only one tilted optical mode. This optical mode is a tilted optical mode (1220) within the cavity (1203) and exists as a standing wave (1223) in the space between the laser and the external mirror (1230). As the positive feedback occurs for only one mode, this enables lasing in this tilted optical mode only. Light comes out (1233) through the semitransparent mirror (1230). This design provides additional stabilization of the wavelength of laser radiation.

Slowing Down Light Propagation in Tilted Cavity Laser

Tilting of the optical wave from the direction parallel to the surface of the epiwafer enables reduction of the group velocity of the light in the tilted cavity laser. The reduction in the velocity of propagation of the light in the direction of the p-n junction plane for tilted cavity lasers can be used in mode-locked lasers to reduce the repetition frequency. Since the mode-locking frequency is defined by the group photon velocity divided by the length of the cavity of the device, going to moderate, for example, 4 GHz frequencies, requires lengths of about 1 cm in conventional edge-emitting lasers. These lengths are above the level of acceptance of monolithic diode laser technology. Thus, tilted cavity lasers offer an additional advantage of compact devices, where needed.

If the resonant optical mode generated by a tilted cavity laser has a small tilt angle θ with respect to the direction normal to the p-n junction plane, the effective velocity of the propagation of light in the p-n junction plane is reduced with respect to the velocity of propagation in the homogeneous medium approximately by a factor of sin θ.

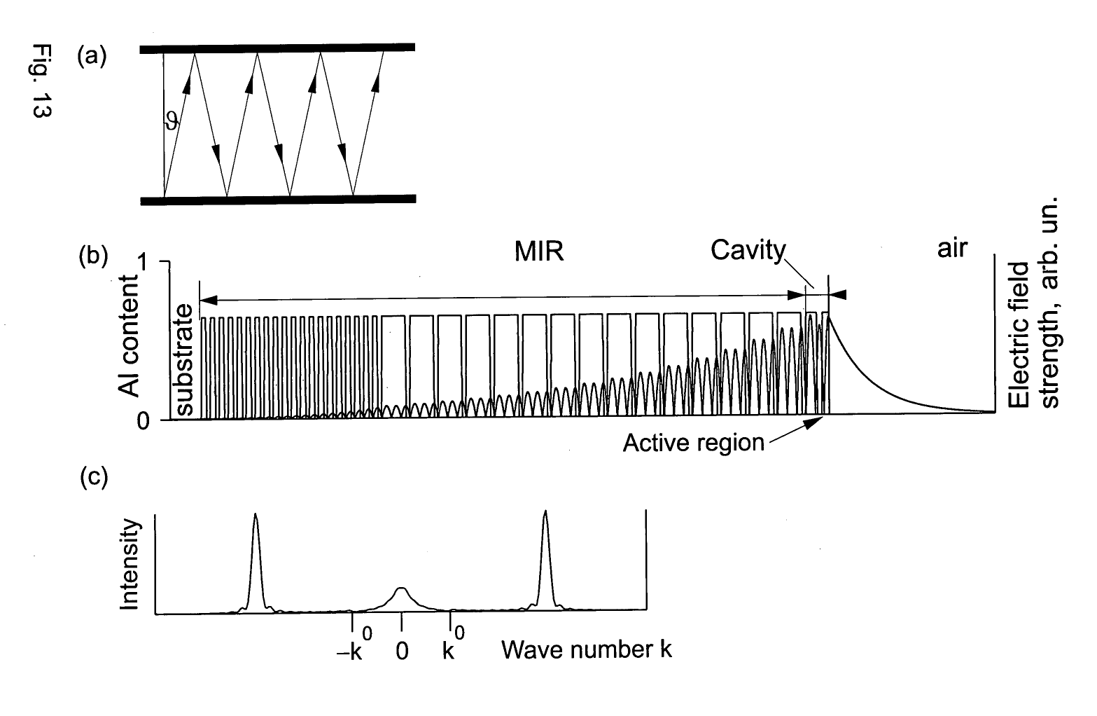

FIG. 13(a) shows a model waveguide including two metal surfaces sandwiching a layer of air. An elementary consideration of propagating light where photons are treated as particles yields the effective velocity of the propagation of light along the waveguide as
v_{eff}=c sin θ. (13)

A rigorous treatment of propagation of light in a waveguide includes calculating the eigenmodes, the effective refractive index of the modes as a function of the wavelength of light, n_{eff}=n_{eff}(λ), and further calculation of the group index,

$${n}_{gr} ( λ ) = {n}_{eff} ( λ ) - λ \frac{\partial {n}_{eff} ( λ )}{\partial λ} . \qquad ( 14 )$$

FIG. 13(b) shows a sample structure of a tilted cavity laser, where the cavity and the MIR are selected such that the resonant optical mode having the minimum losses propagates at an angle tilted 17.3 degrees with respect to the direction normal to the p-n junction plane. This angle is very close (but still larger) to the angle of the total internal reflection at the semiconductor/air interface. An advantage of choosing such an angle is that the electric field is present in the air close to the laser structure in the form of an evanescent field, exhibiting an exponential decay at a rather long distance of a few micrometers.

FIG. 13(c) shows a Fourier power spectrum of the resonant optical mode in the vertical direction. The spectrum reveals two side maxima related to an oscillatory decay of the optical mode in a multilayer interference reflector, and a central maximum related to an exponential decay of the optical mode in the air. The two wave numbers ±k₀ refer to the condition of the total internal reflection at the semiconductor/air interface at a laser facet. The portion of the optical power related to the interval between these two values can come out of the laser structure if the front facet is covered by an antireflecting coating. For this particular structure, up to 15% of the total optical power can come out of the structure.

Table 1 demonstrates the effective slowing down of the group velocity of the tilted optical mode calculated for a tilted cavity laser structure shown in FIG. 13(b) and emitting at 1250 nm. The reference edge-emitting laser in the table includes a 400 nm GaAs waveguide sandwiched between Ga_{0.7}Al_{0.3}As cladding layers. The first tilted cavity laser listed in the table contains a multilayered interference reflector (MIR) with effective 3λ/4-layers. The second tilted cavity laser in the table contains a MIR with effective 5λ/4-layers. Both of the examples of tilted cavity lasers shown in the table slow down the group velocity of the tilted optical mode by a factor greater than 2 compared to the reference edge-emitting laser.

| | | Group | |
|---|---|---|---|
| | Effective angle, | refractive | |
| Structure | degrees | index | Slowing down |
| Reference edge- | 84.8 | 3.517 | |
| emitting laser | | | |
| First Tilted Cavity | 17.3 | 7.560 | by a factor of 2.15 |
| Laser | | | |
| Second Tilted | 17.3 | 8.521 | by a factor of 2.42 |
| Cavity laser | | | |

If the effective tilt angle of the resonant tilted optical mode is smaller than the angle of the total internal reflection at a semiconductor/air interface, light comes out through the top surface, for example, in the case when part of the MIR layers are locally removed. In that situation, it is possible to achieve even stronger slowing down of the group velocity of light propagation along the waveguide and to construct tilted cavity lasers with an output through the top mirror.

Enhancement of the Wavelength Selectivity

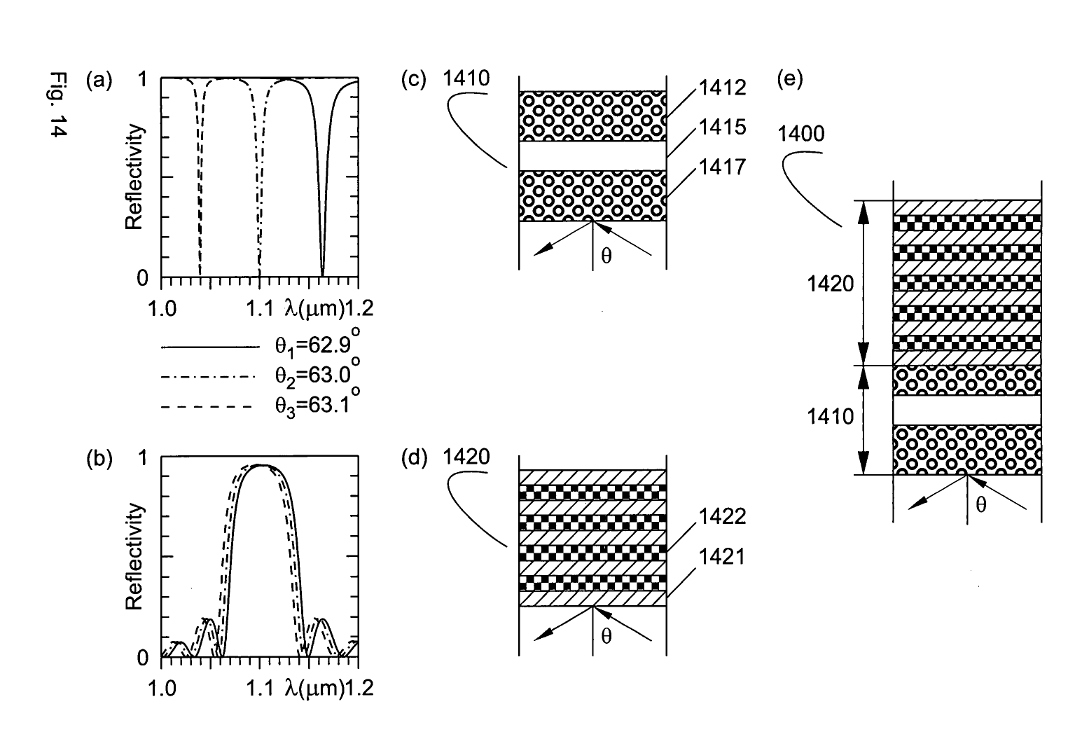

FIG. 14 shows a schematic diagram illustrating the principle of an additional stabilization of the wavelength of laser radiation in a tilted cavity laser. The wavelength stabilization is based on the selectivity of leaky losses to the substrate as a function of the wavelength. The leaky losses are related to the dip width in the reflectivity spectrum of a structure. FIG. 14 illustrates the principle of this additional enhancement of selectivity. FIG. 14(c) shows schematically a novel element of a tilted cavity laser structure. This is a high-finesse cavity (1410), where a high-index layer (1415) is sandwiched between two low-index layers (1412) and (1417) such that for a given tilt angle θ, the optical mode exists in the layers (1412) and (1417) in the form of an evanescent wave. This means that the tilt angle θ exceeds the angle of total internal reflectance at the boundary between the reference layer and each of the low-index layers (1412) and (1417). Preferably, for a given tilt angle θ, the Q-factor of this high-finesse cavity is larger than 5.

FIG. 14(a) shows the reflectivity spectra of a high-finesse cavity at three different values of the tilt angle θ. The parameters of the cavity, shown schematically in FIG. 14(c), are as follows. The layer (1415) has a thickness of 365 nm and is formed of Ga₁₋ₓAlₓAs with x=0.6. The layers (1412) and (1417) have a thickness of 1000 nm each and are formed of Ga₁₋ₓAlₓAs with x=0.8. The refractive indices of these layers for a wavelength of light of 1100 nm equal 3.1688 and 3.0585 respectively. A major feature of the reflectivity spectra of FIG. 14(a) is a fast shift of the dip position with the angle, about 600 nm/degree.

FIG. 14(d) shows schematically a multilayered interference reflector including a periodic structure of alternating layers of high (1421) and low (1422) refractive indices. FIG. 14(b) shows schematically the reflectivity spectra of the multilayered interference reflector of FIG. 14(d) at three different angles. The parameters of the multilayered interference reflector are as follows. The layer (1421) is formed of GaAs, and has a thickness of 174 nm. The layer (1422) is formed of Ga₁₋ₓAlₓAs with x=0.1 and has a thickness of 187 nm. The refractive indices for a wavelength of 1100 nm equal 3.4812 and 3.4328, respectively. A major feature of the reflectivity spectra of FIG. 14(b) is a relatively slow shift of the reflectivity maximum with the angle, about 100 nm/degree.

FIG. 14(e) shows schematically a structure (1400) composed of the high-finesse cavity (1410) and the multilayered interference reflector (1420). A major property of this structure is that the features in the reflectivity spectra of two constituents shift with the angle θ with strongly different rates. Thus, if these features coincide with the wavelengths at a certain angles, two constituents are driven apart as the angle changes. Thus, the reflectivity spectrum of the composed structure has a relatively narrow dip at a certain angle and a certain wavelength, and this dip significantly broadens at a different angle. Table 2 illustrates the resulting dip width:

| Wavelength λ, nm | Dip width Δλ, nm |
|---|---|
| 1160 | >8 |
| 1140 | >4 |
| 1100 | 1.4 |
| 1060 | >7 |
| 1040 | >10 |

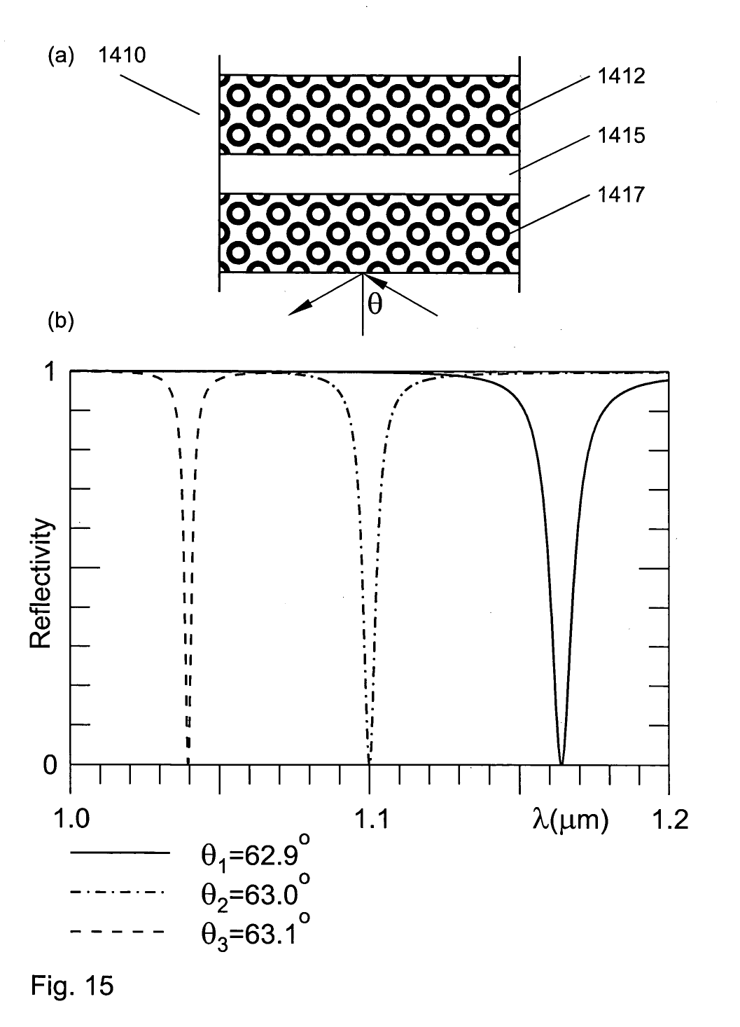

FIG. 15(a) and FIG. 15(b) show FIG. 14(c) and FIG. 14(a) at a larger magnification.

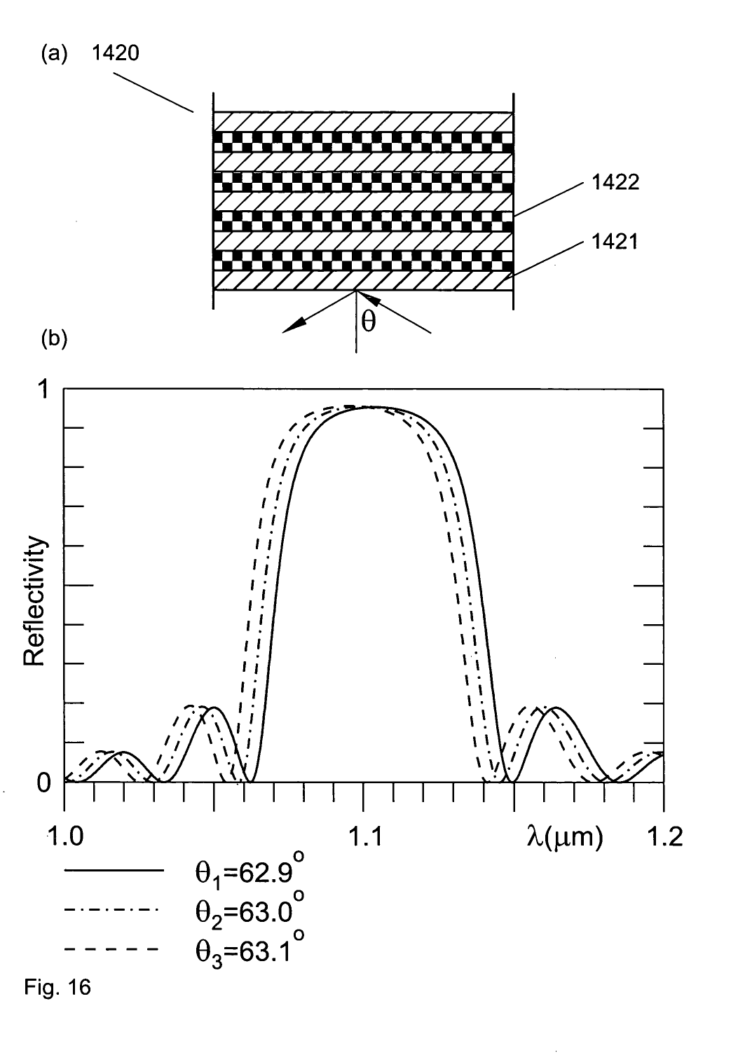

FIG. 16(a) and FIG. 16(b) show FIG. 14(d) and FIG. 14(b) at a larger magnification.

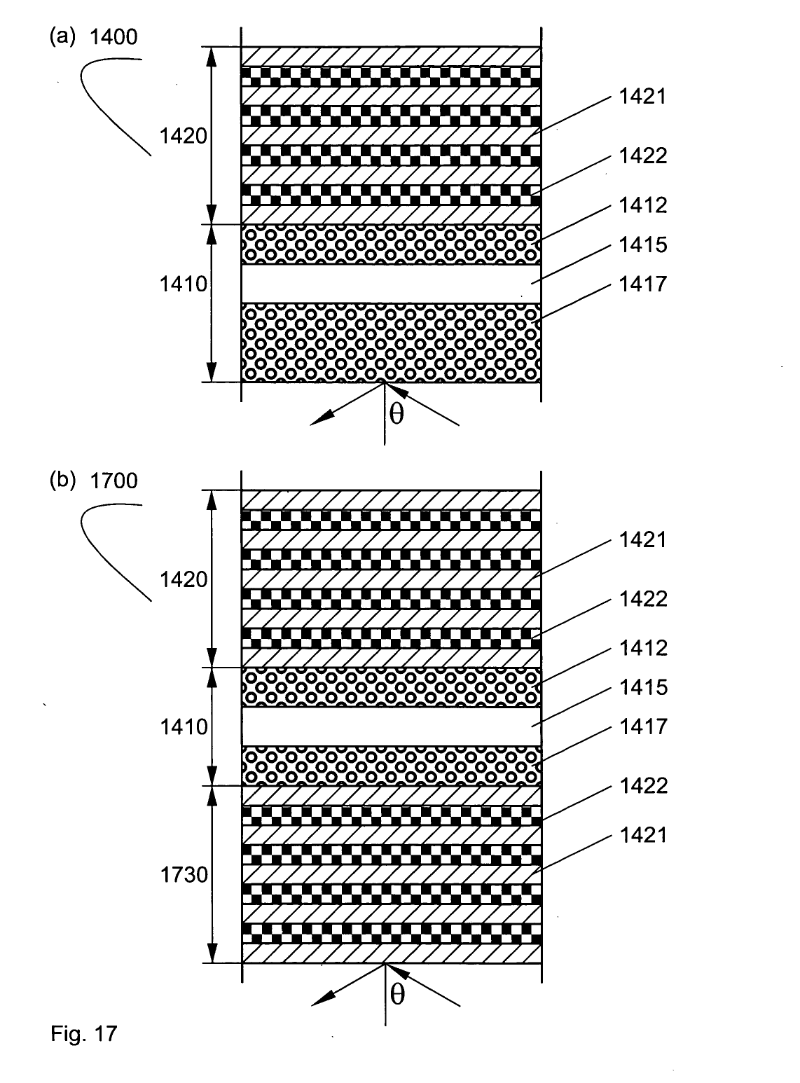

FIG. 17(a) shows FIG. 14(e) at a larger magnification.

FIG. 17(b) shows schematically a composed laser structure (1700) including a high-finesse cavity (1410) sandwiched between two multilayered interference reflectors (1420) and (1730). In a preferred embodiment of the present invention, one reflector (1420) is an n-doped reflector, and the other reflector (1730) is a p-doped reflector.

Within the concept of a high-finesse cavity and a multilayered interference reflector, where the average refractive index of a high-finesse cavity differs from the average refractive index of a multilayered interference reflector by at least 2%, the selectivity of leaky losses of the tilted optical mode to the substrate or the contact layers is governed by the width of a spike in the reflectivity spectrum of a multilayered interference reflector.

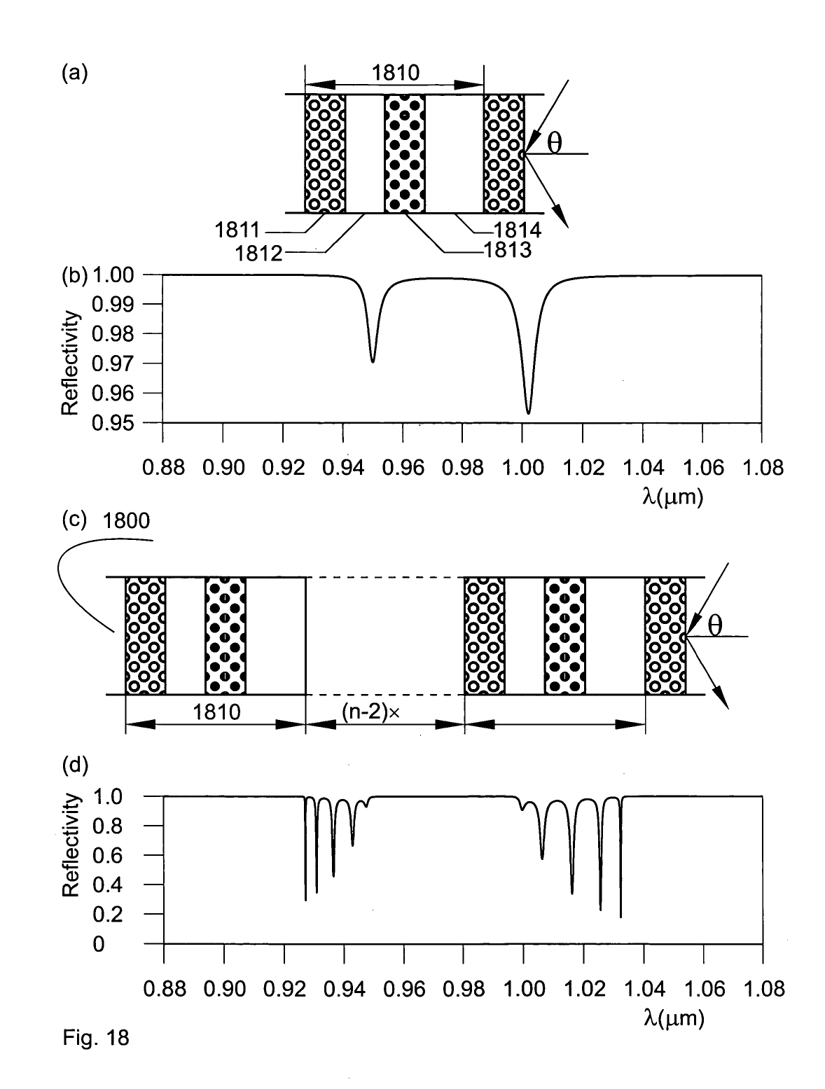

FIG. 18(a) through FIG. 18(d) illustrate the principle of reducing the width of the spike. The multilayered interference reflector includes the properties of an optical filter for tilted modes, providing a high reflectivity within a relatively narrow spike and a significantly lower reflectivity outside the spike. The reflector includes a periodic structure, where every period is more complex than just two layers. FIG. 18(a) illustrates schematically the element (1810) including a low-index layer (1811) followed by a high-index layer (1812) followed further by a low-index layer (1813) followed by a high-index layer (1814). FIG. 18(b) shows the reflectivity spectrum of the structure (1810). The reflectivity is calculated for a particular example, where the high-index layers (1812) and (1814) are formed of GaAs with a refractive index of 3.5235 at the wavelength of 980 nm, and the low-index layers (1811) and (1813) are formed of Ga₁₋ₓAlₓAs with x=0.8 and a refractive index of 3.0812 at the wavelength of 980 nm. The thickness of the first layer (1811), second layer (1812), third layer (1813), and fourth layer (1814) is 500 nm, 366 nm, 500 nm, and 386 nm, respectively. The reflectivity spectrum is calculated at a tilt angle of θ=63°. The reflectivity spectrum reveals two dips at two different wavelengths originating from the two cavities having different thicknesses. FIG. 18(c) shows the multilayered interference reflector (1800) formed by the periodic n-time repetition of the element (1810). FIG. 18(d) shows the reflectivity spectrum of the multilayered interference reflector of FIG. 18(c) for n=5 periods. Each of the two dips of FIG. 18(b) is split in five.

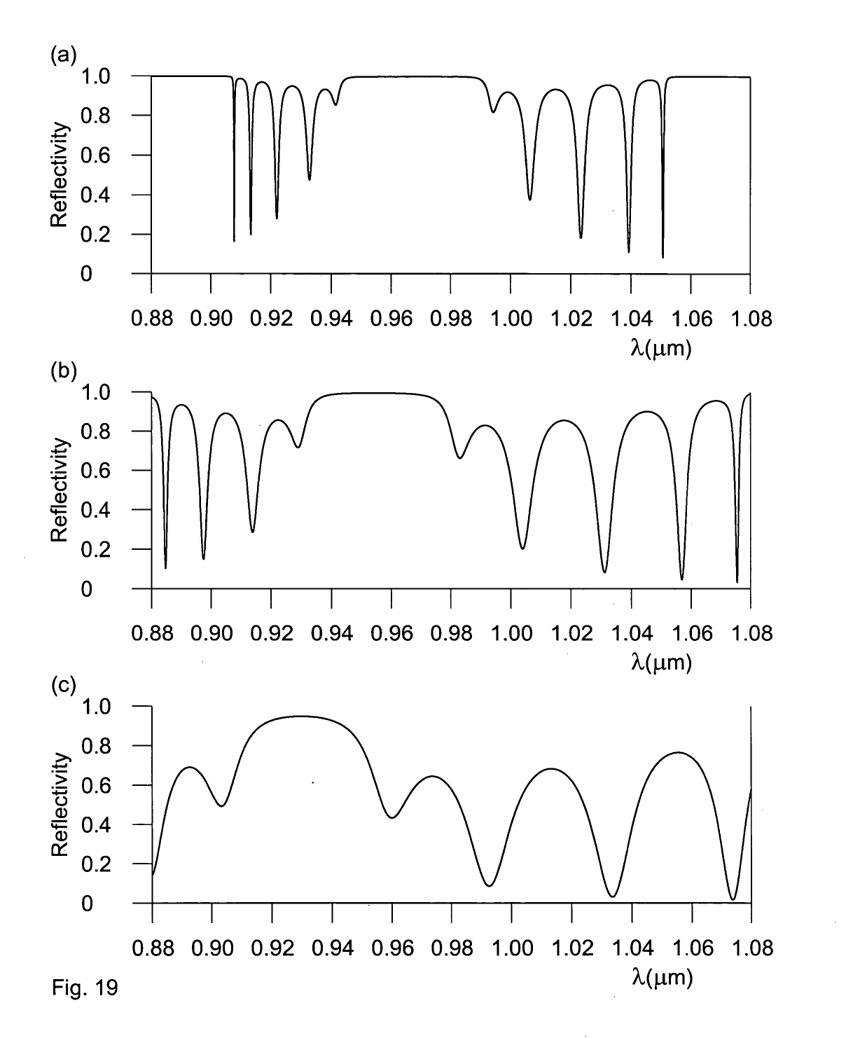

FIG. 19(a) through FIG. 19(c) show the evolution of the reflectivity spectrum of FIG. 18(d) when the thickness of the low-index layers is reduced. The thickness of the low-index layers (1811) and (1813) equals 400 nm for FIG. 19(a), 300 nm for FIG. 19(b), and 200 nm for FIG. 19(c). The trend of reducing the thickness of the low-index layers leads to i) the width of the central spike decreasing; ii) the maximum reflectivity of the central spike decreasing, iii) the reflectivity of the neighboring spikes decreasing faster than that of the central spike, and iv) the central spike shifting toward shorter wavelengths.

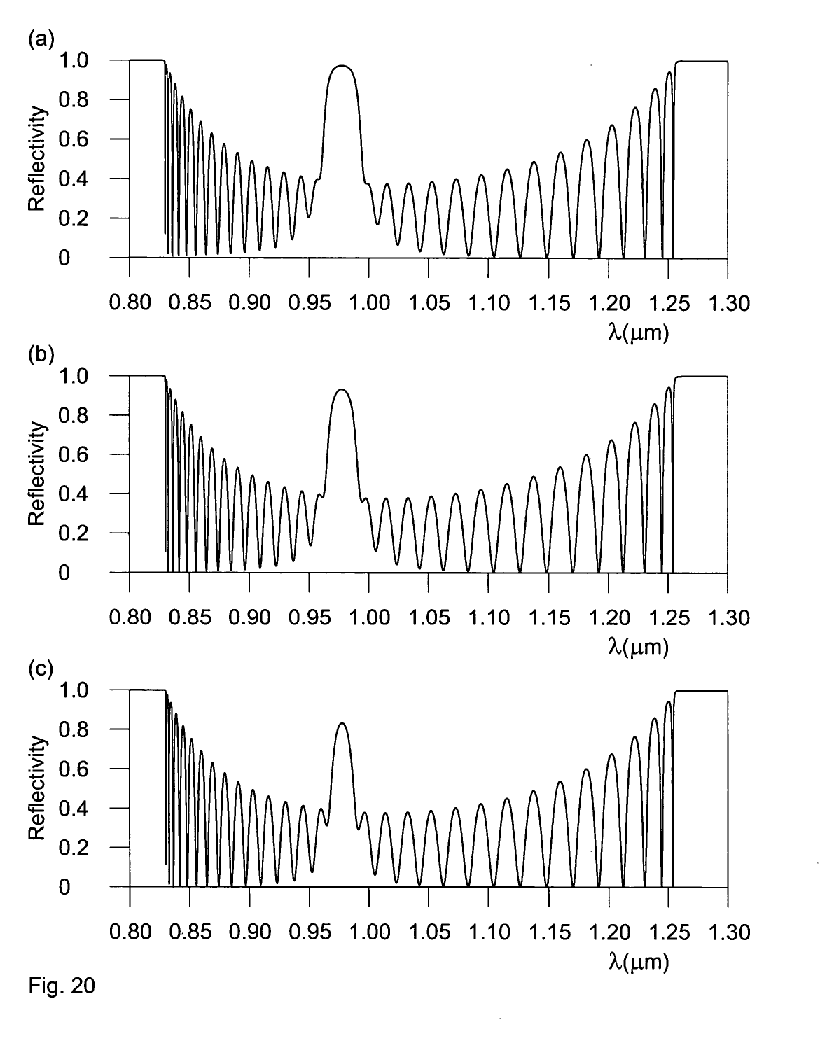

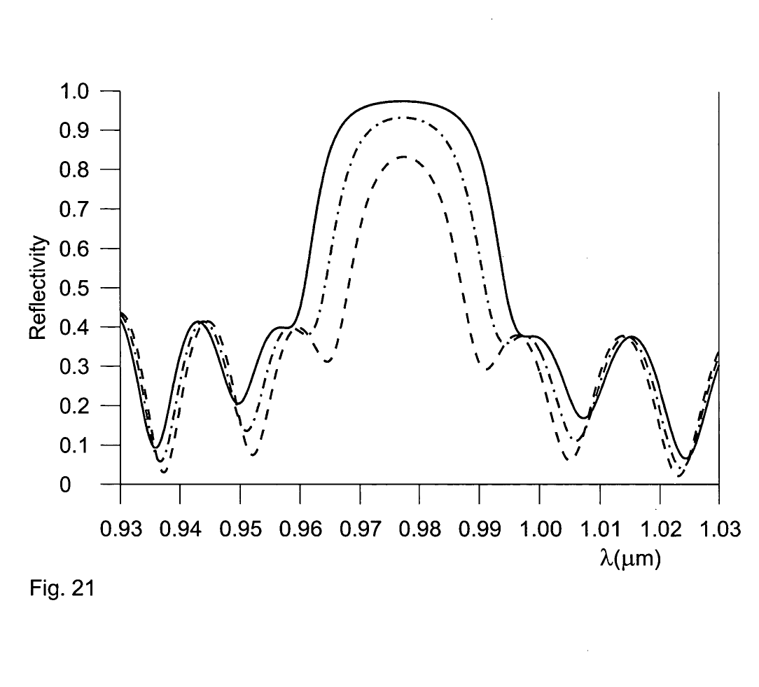

In order to keep the central spike at the wavelength of 980 nm, the thicknesses of the layers are rescaled as necessary. FIG. 20(a) through FIG. 20(c) show the reflectivity spectrum of a multilayered interference reflector including 15 periods. The thickness of the first high-index layer (1812) is 404 nm. The thickness of the second high-index layer (1814) is 418 nm. The thicknesses of the low-index layers (1811) and (1813) are equal with a value of 140 nm for FIG. 20(a), 130 nm for FIG. 20(b), and 120 nm for FIG. 20(c). A trend with decreasing the thicknesses of low-index layer is illustrated in FIG. 21, where the central spikes of FIG. 20(a) through FIG. 20(c) are shown at larger magnifications. As the thickness decreases, the central spike becomes narrower, and its maximum reflectivity decreases. Thus, FIG. 20(a) through FIG. 20(c) show that the considered structure has the properties of an optical filter providing efficient reflectivity within the central spike and a significantly lower reflectivity in a broad spectral range at both shorter and longer wavelengths.

When a design of a tilted cavity laser is constructed of elements, namely, of a high-finesse cavity and a multilayer interference reflector (MIR) having a narrow reflectivity spike, it is possible to calculate all the optical modes. The perfectly matched layer (PML) method is preferably used to perform these calculations.

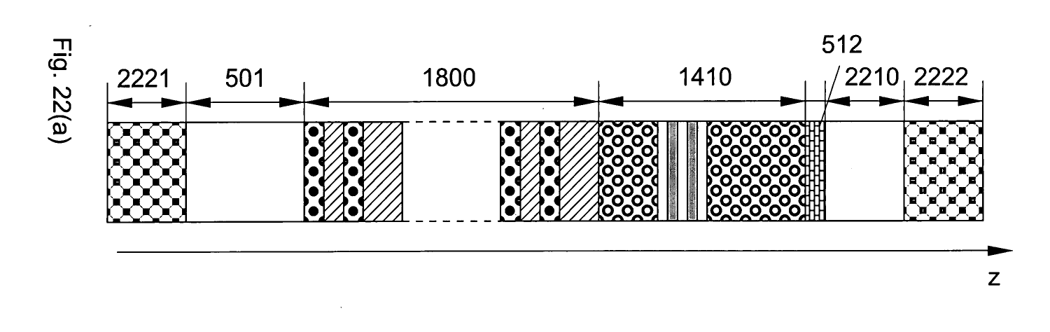

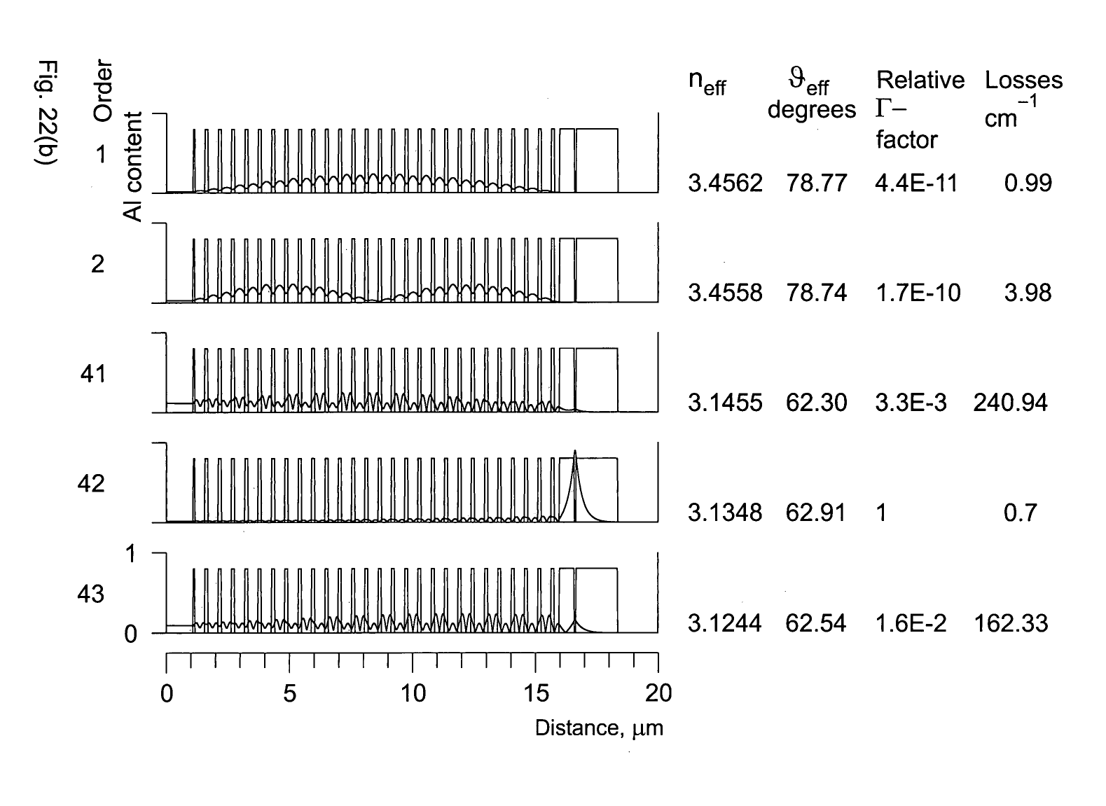

FIG. 22(a) shows a structure used in the model PML calculations. The model structure includes the substrate (501), the MIR (1800), the cavity (1410), the p-contact (512), and the air layer (2210). The MIR (1800) includes 14 periods of the structure (1810), and the thickness of the low-index layers (1811) and (1813) is 130 nm. In this example, the thickness of the first high-index layer (1812) is 404 nm, and the thickness of the second high-index layer (1814) is 418 nm. The physical structure is surrounded by two fictitious layers, the first PML layer (2221) and the second PML layer (2222). In the PML method the problem is formulated as an eigenvalue problem for the equation:

$$- q ( z ) \frac{\partial }{( \frac{2 π}{λ} ) \partial z} [ q ( z ) \frac{\partial }{( \frac{2 π}{λ} ) \partial z} {E}_{y} ( z ) ] - {n}^{2} ( z ) {E}_{y} ( z ) = - {n}_{eff}^{2} ( z ) {E}_{y} ( z ) . \qquad ( 15 )$$

The function q(z)=1 within the real physical structure, and

$$q ( z ) = \frac{1}{1 - \frac{i σ ( z )}{ω {ɛ}_{0} {n}_{p}^{2} ( z )}} , \qquad ( 16 )$$

where ε₀ is the vacuum dielectric constant, σ(z) is the conductivity of the PML, and nₚ(z) is the refractive index of the PML. Boundary conditions read
E_{y}(z)=0 (17)
at the outer boundaries of the PMLs.

Within the physical structure, Eq. (15) coincides with the Maxwell's equation for the TE optical mode. The specific choice of the fictitious parameters of the PMLs, σ(z) and nₚ(z), ensures the fact that electromagnetic wave in any optical mode, impinging on a PML from the physical structure is not reflected back. This approach refers to the physical approximation that all optical modes impinging on the substrate from the structure are completely absorbed in the substrate and/or scattered at the n-contact and are not reflected back.

A few calculated optical modes are plotted in FIG. 22(b). The calculations show the following. First, the effective angle decreases with the mode number. Second, only one mode has a reasonable confinement factor in the active medium. Thus, this mode, which, for the particular structure is the 42nd mode, may be regarded as a resonant optical mode as it has a strong enhancement of the confinement factor in the active medium. The spatial profile of the resonant optical mode reveals a strong maximum in the high-finesse cavity and an oscillatory decay within the multilayered interference reflector away from the cavity.

To illustrate the dependence of the spatial profile of the tilted optical mode on the wavelength, this profile is plotted for three different wavelengths at larger magnification. The profile within the high-finesse cavity reveals hardly any difference, and the dramatic difference occurs within the multilayered interference reflector.

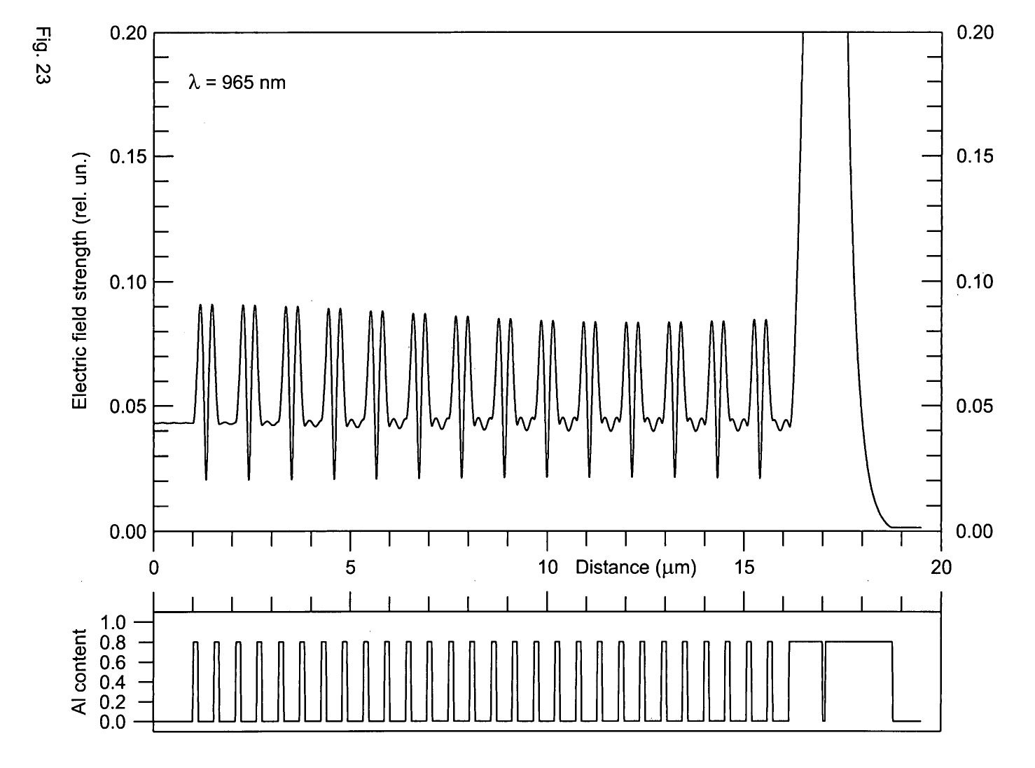

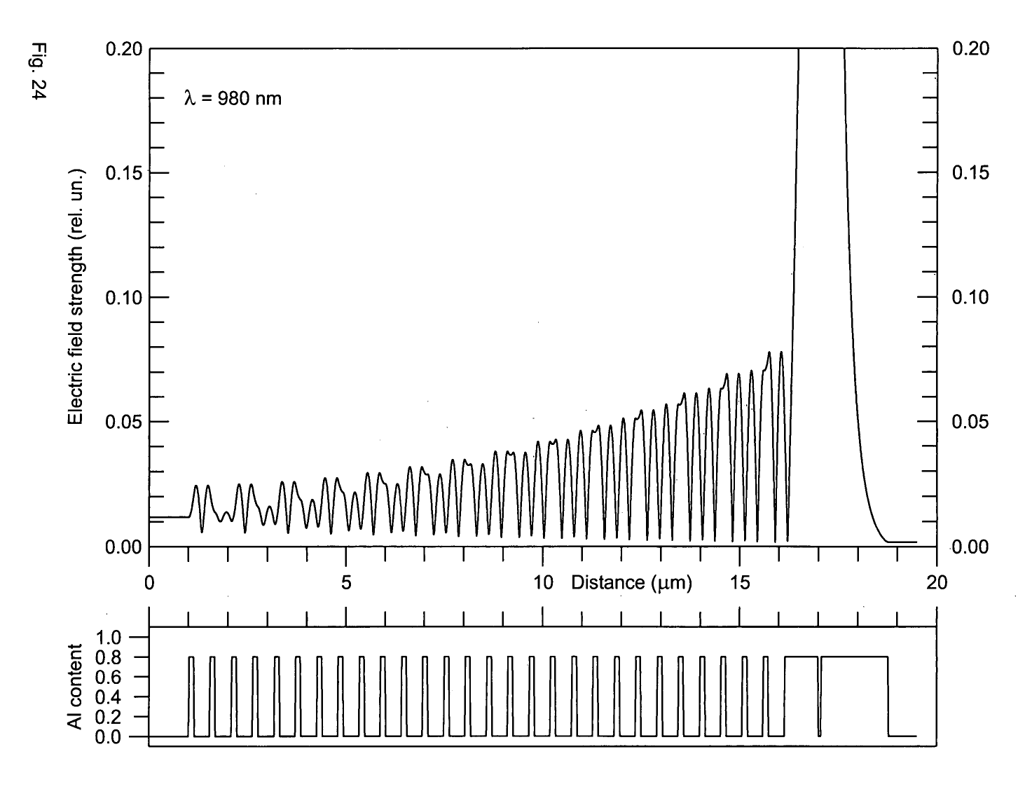

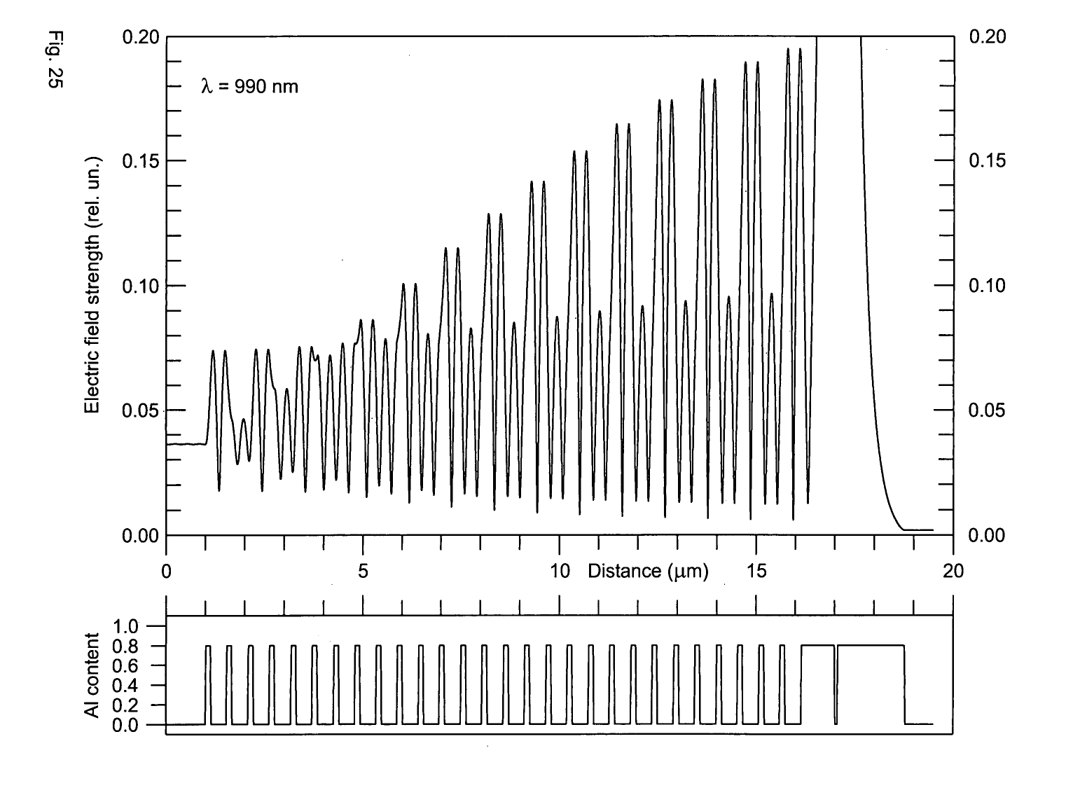

FIG. 23 through FIG. 25 show the spatial profile at wavelengths of 965 nm, 980 nm, and 990 nm, respectively. The non-zero spatial profile at the z-coordinate between 0 and 1 μm is due to leaky losses into the substrate. FIG. 23 through FIG. 25 show that the leaky losses are significantly larger at 965 nm and 990 nm than at 980 nm. The calculation of leaky losses yields the value of 9.5 cm⁻¹ at a wavelength of 965 nm, 0.7 cm⁻¹ at a wavelength of 980 nm, and 6.7 cm⁻¹ at a wavelength of 990 nm, thus showing a strong selectivity of the leaky losses as a function of wavelength. This selectivity yields an efficient wavelength stabilization for a tilted cavity laser of the present invention.

It will be appreciated by those skilled in the art that the resulting structure of a tilted cavity laser can be described in different terms. For example, one may construct a narrow cavity having a high refractive index bounded by two cladding layers having a lower refractive index, just as the cavity (1410) in FIG. 22(a). This narrow cavity may then have only a single localized optical mode. One may then choose one rather narrow cladding layer to ensure high leakage losses of this optical mode into the substrate. Then one may attach a multilayered structure, which will work as a wavelength-selective mirror promoting a high reflection of the leaking optical mode back to the cavity only in a narrow spectral interval. A laser constructed in such a way will be the same tilted cavity laser as described herein. This will necessarily include a high-finesse cavity and a multilayer interference reflector designed such that the spectral position of the cavity reflectivity dip coincides with the spectral position of maximum reflectivity of the MIR at only one angle, and the two draw apart fast, as the angle deviates from the optimum value. The design, as described above, has been chosen, as an example only, to clarify the way a tilted cavity laser can be constructed of single elements.

It should be noted that the wavelength of the tilted cavity lasers described in FIG. 14 through FIG. 25 is governed by the matching conditions between a high-finesse cavity and a multilayered interference reflector. When the refractive indices change due to temperature variations, the resonant wavelength changes as well.

Temperature dependence of the refractive indices is typically determined from experimental measurements. Another possibility is to use some empirical models, which yield temperature dependence of n(λ). As an example, one such model is referred to in a paper by V. Bardinal, R. Legros, and C. Fontaine, “In situ measurement of AlAs and GaAs refractive index dispersion at epitaxial growth temperature”, Applied Physics Letters, Vol. 67 (2), pp. 244-246 (1995). The temperature variation of the refractive index is related to the temperature variation of the energy band gap:

$$\frac{1}{n ( λ )} \frac{ⅆ n ( λ )}{ⅆ T} = - \frac{1}{4 {E}_{g}} \frac{ⅆ {E}_{g}}{ⅆ T} . \qquad ( 16 )$$

A straightforward integration of Eq. (16) yields:

$$n ( λ ; T ) = n ( λ ; {T}_{0} ) {( \frac{{E}_{g} ( {T}_{0} )}{{E}_{g} ( T )} )}^{1 / 4} . \qquad ( 17 )$$

For a tilted cavity laser based on a GaAs/GaAlAs structure, the temperature dependence of the energy band gap is described by an empirical formula. A model given by D. E. Aspnes (Physical Review, “GaAs lower conduction-band minima: Ordering and properties”, B14 (12), pp. 5331-5343 (1976)) states that for the energy band gap at the Γ-point of the Brilluin zone:

$${E}_{Γ} ( T ) = {E}_{Γ} ( 0 ) - 5.41 \times {10}^{- 4} \times \frac{{T}^{2}}{T + 204} , \qquad ( 18 )$$

where T is the absolute temperature in Kelvin, and the energy is calculated in electron-volts (eV), and for the Ga₁₋ₓAlₓAs alloy the value E_{Γ}(0) is given by:
E_{Γ}(0)=1.519+1.155x+0.37x². (16)

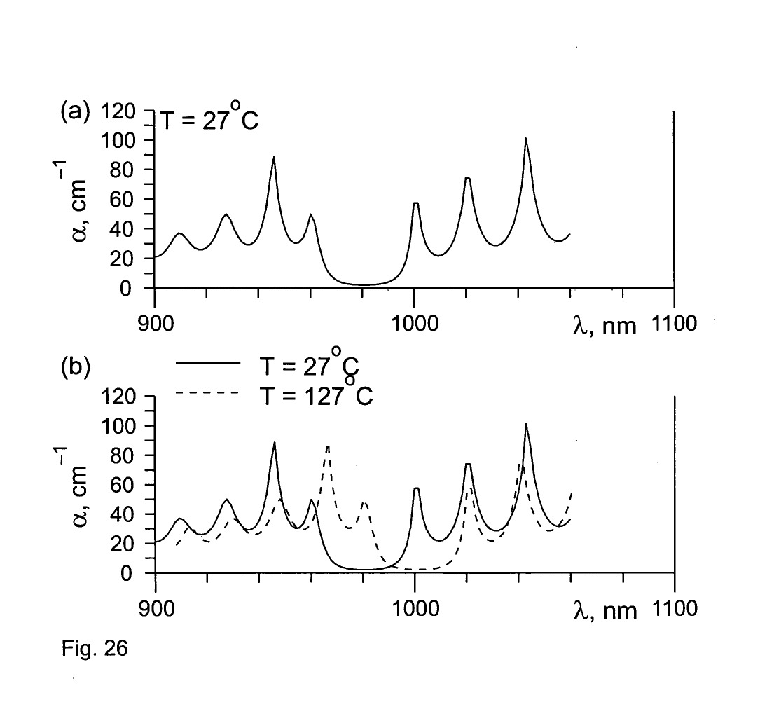

FIG. 26(a) shows a dependence of the leakage losses versus wavelength for a tilted cavity laser designed to emit laser light at 1290 nm. It is designed following the concept disclosed in the present invention, but the layer thicknesses are adjusted for a required wavelength of 1290 nm. FIG. 26(b) shows the dependence of the leakage losses versus wavelength at two temperatures, 27° C., and 127° C. The wavelength corresponding to the minimum leakage shifts by 25 nm when the temperature increases by 100 degrees. Thus, the average wavelength shift is 0.25 nm/degree.

Several approaches are possible to control and further reduce the temperature shift of the resonant wavelength. In an embodiment of the present invention, the average refractive index of the MIR is lower than the average refractive index of the high-finesse cavity. For a GaAs/GaAlAs structure, this implies that the average Al content in the MIR is higher than the average Al content in the cavity.

It follows from Eq. (11), Eq. (16), and Eq. (17), that the refractive index of GaAs or GaAlAs with a low aluminum content increases with temperature faster than that of GaAlAs with a high aluminum content. Thus, for example, an average refractive index of a two-layered structure including a layer of GaAs of a thickness d, and a layer of Ga₁₋ₓAlₓAs having the same thickness d and an aluminum content x=0.8, increases faster with temperature than the refractive index of a Ga₁₋ₓAlₓAs layer having a thickness 2d and an aluminum content x=0.4. In yet another embodiment of the present invention, a high-finesse cavity including thick layers of GaAlAs with high aluminum content, preferably higher than 60%, additionally includes one or a few thin insertions of GaAs or GaAlAs with low aluminum content, preferably lower than 35%, inserted into the layers of high aluminum content. This approach enhances the rate of the temperature variation of the average refractive index of the high-finesse cavity. It is thus possible to ensure that the rate of temperature variation of the refractive index of the high-finesse cavity is close to that of the MIR, which substantially reduces the temperature shift of the resonant wavelength of the tilted cavity laser.

Thin Layers in the MIR for Further Enhancement of the Wavelength Selectivity of Leakage Losses

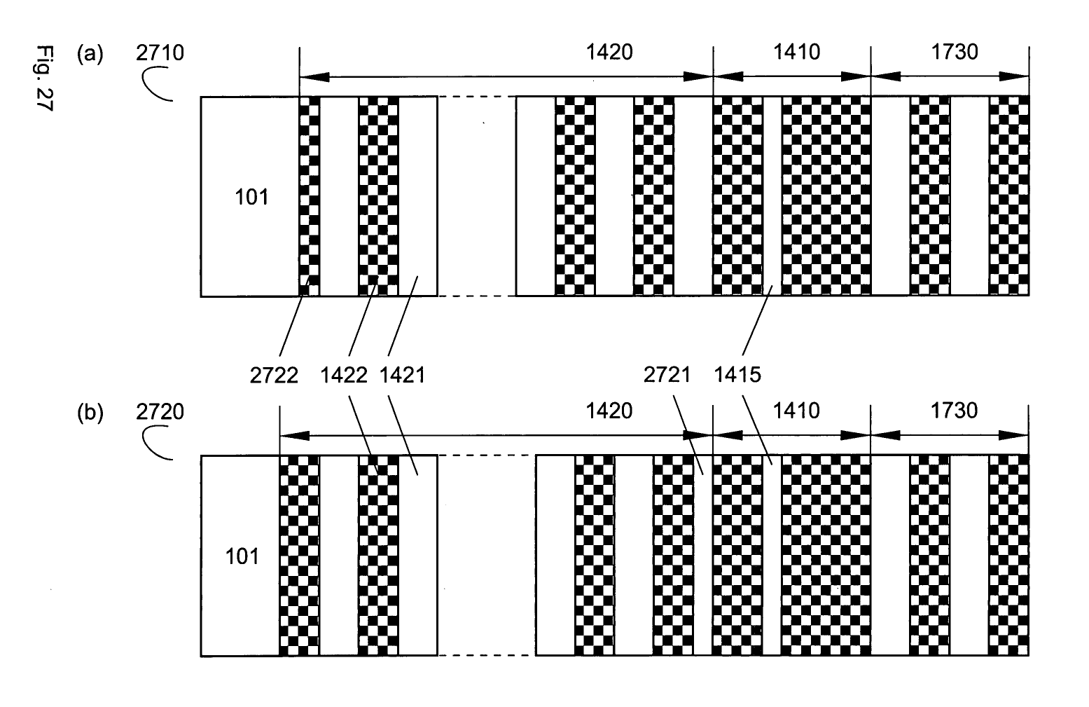

FIG. 27(a) shows schematically another embodiment of the present invention, where a tilted cavity laser (2710) includes a multilayered interference reflector (MIR) (1420), where the MIR (1420) includes a periodic structure of alternating layers having a first refractive index (1421) and a second refractive index (1422). The second refractive index is lower than the first refractive index. A novel feature of this MIR is that the second-refractive index MIR layer (2722) most remote from the cavity has a thickness smaller than the other second-refractive index MIR layers (1422). In a preferred embodiment, the thickness of the remote layer (2722) is smaller than the thickness of the other layers (1422) by a factor ranging from 0.3 to 0.8. Due to a smaller thickness of the remote layer (2722), the spectral selectivity of the leakage losses through the MIR is enhanced.

FIG. 27(b) shows schematically another embodiment of the present invention, where a tilted cavity laser (2720) includes a multilayered interference reflector (MIR) (1420), where the MIR (1420) includes a periodic structure of alternating layers having a first refractive index (1421) and a second refractive index (1422). The second refractive index is lower than the first refractive index. A novel feature of this MIR is that the first-refractive index MIR layer (2721) closest to the cavity has a thickness smaller than the other first-refractive index MIR layers (1421). In a preferred embodiment, the thickness of the closest layer (2721) is smaller than the thickness of the other layers (1421) by a factor ranging from 0.3 to 0.8. Due to a smaller thickness of the closest layer (2721), the spectral selectivity of the leakage losses through the MIR is enhanced.

In another embodiment of the present invention, both the second-refractive index MIR layer (2722) most remote from the cavity has a thickness smaller than the other second-refractive index MIR layers (1422), and the first-refractive index MIR layer (2721) closest to the cavity has a thickness smaller than the other first-refractive index MIR layers (1421).

Fine Tuning of the Resonance Wavelength

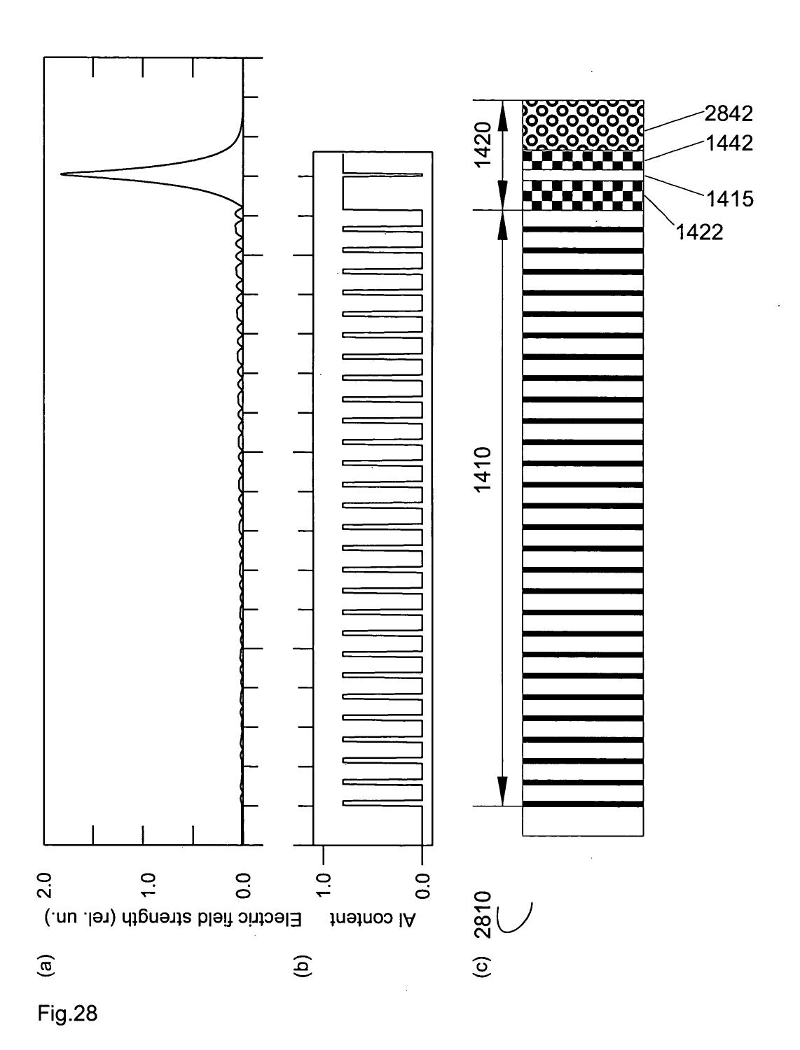

FIG. 28(a) through FIG. 28(c) illustrate schematically a method for the fine-tuning of the wavelength generated by a tilted cavity laser of the present invention. FIG. 28(a) shows schematically a spatial profile of the resonant tilted optical mode, similar to FIG. 22(a). FIG. 28(b) shows schematically a spatial profile of the aluminum content for a laser based on a GaAs/GaAlAs waveguide, similar to FIG. 22(b). FIG. 28(c) shows schematically a tilted cavity laser (2810), including a cavity (1420) and an MIR (1410). The cavity (1420) includes a semiconductor layer (1422), an active region (1415), a semiconductor layer (1442), and a dielectric layer (2842).

The electric field of the resonant optical mode decays away from the active region in the layers (1442) and (2842). By varying a thickness and a refractive index of the layer (2842), it is possible to tune the wavelength of the resonant optical mode. The tuning is preferably realized by the following method.
1. A semiconductor structure is grown that terminates by the semiconductor layer (1442).
2. The structure is processed, and a laser is fabricated.
3. The wavelength of the generated laser light is measured. Depending on the measured wavelength of the emitted laser light and a required wavelength, a necessary thickness of the dielectric layer is calculated.
4. The dielectric layer with a calculated thickness is deposited.

In another embodiment of the present invention, the method is used to fine-tune the resonant wavelength of an optical amplifier.

In yet another embodiment of the present invention, the method is used to fine-tune the resonant wavelength of a resonant photodetector.

The spectral selectivity of the leaky losses in tilted cavity lasers depends on the physical conditions in the substrate. The described embodiments have been calculated for a situation, where light leaking to the substrate is absorbed in the substrate or the bottom contact (n-contact) or is scattered by the bottom contact. Thus, reflection of light from the bottom contact is neglected in this approach. In certain situations, light leaking into the substrate may be partially reflected back to the structure. In one embodiment of the present invention, the bottom contact is intentionally fabricated to be rough in order to suppress back-reflection of light.

In another embodiment of the present invention back-reflection of light from the bottom contact is a desirable effect. Since the phase of the reflected light is a function of the wavelength, the back reflection may result in an additional strong dependence of the leaky losses on the wavelength of light and thus enhance the selectivity of the leaky losses.

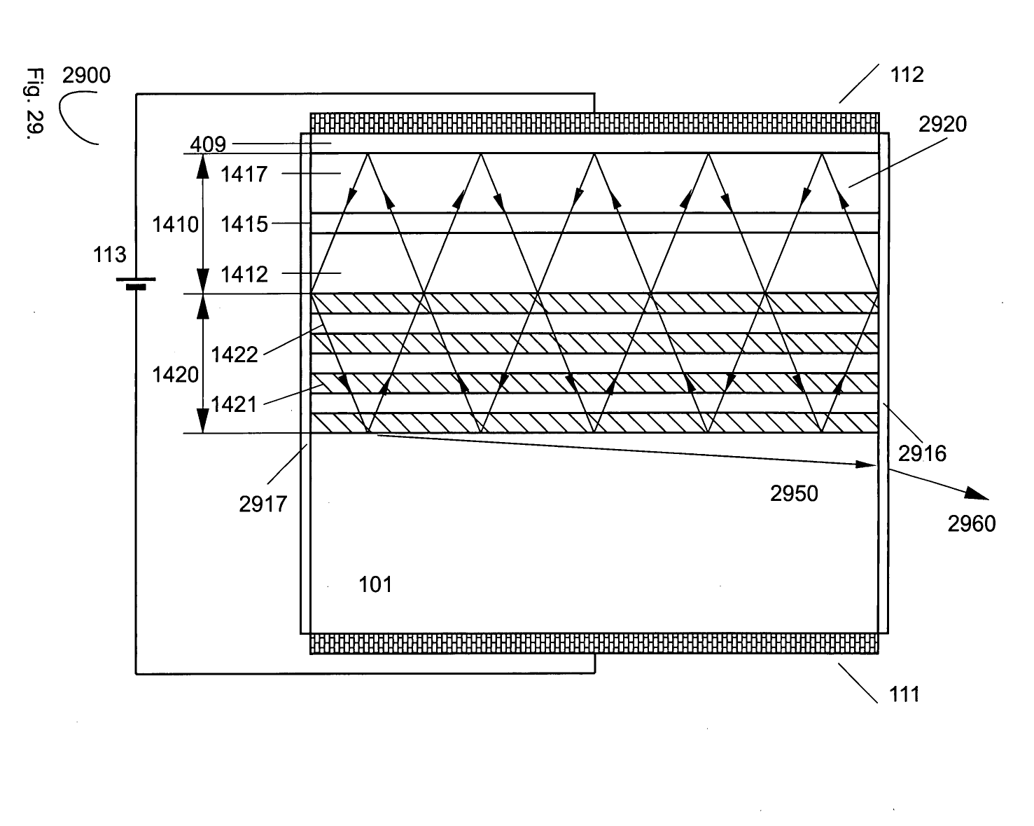

In yet another embodiment of the present invention, laser light generated by a tilted cavity laser comes out in a leaky mode through the substrate. FIG. 29 shows a tilted cavity laser (2900), in which a high-finesse cavity (1410) and an MIR (1420) are designed such that the resonant optical mode (2920) undergoes total internal reflection on both the front facet at an antireflecting coating (2916) and at the rear facet at a high-reflection coating (2917). The light in the resonant optical mode leaks into the substrate (101), where it propagates as a leaky mode (2950), and comes out (2960) through the antireflecting coating (2916).

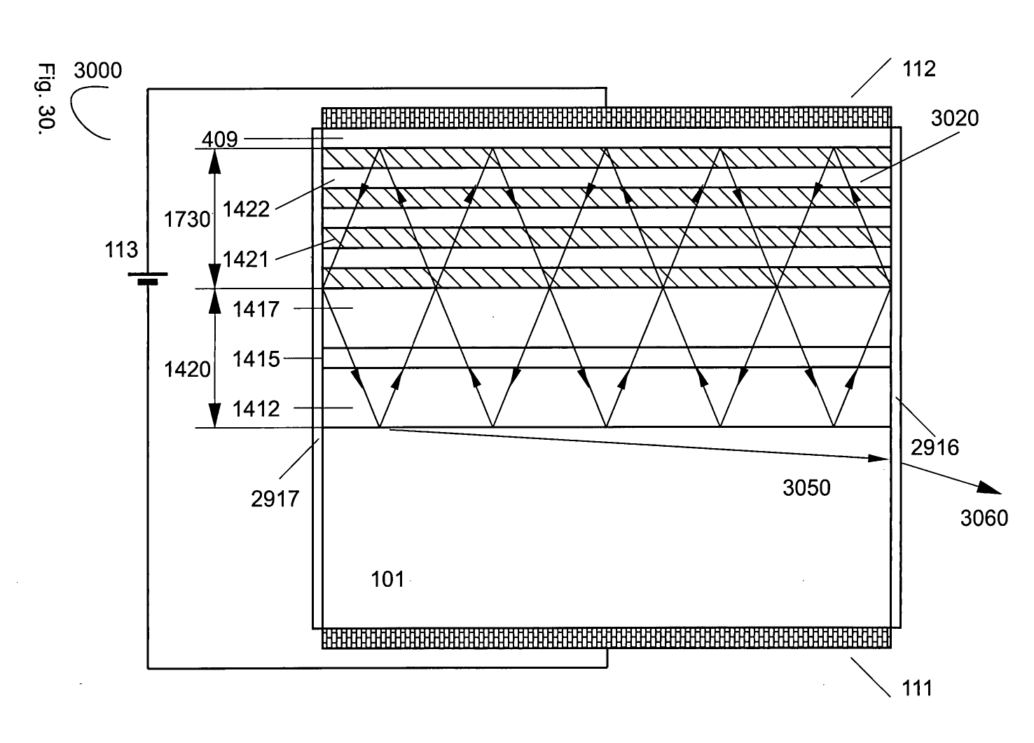

FIG. 30 shows another embodiment of the present invention, where a tilted cavity laser (3000) includes a high-finesse cavity (1420), and an MIR (1730), and where the high-finesse cavity (1420) is placed between the substrate (101) and the p-doped MIR (1730). The laser light in the resonant optical mode (3020) undergoes total internal reflection at both the antireflecting coating (2916) at the front facet and at the high-reflection coating (2917) at the rear facet. The light in the resonant optical mode leaks into the substrate (101), where it propagates as a leaky mode (3050), and comes out (3060) through the antireflecting coating (2916).

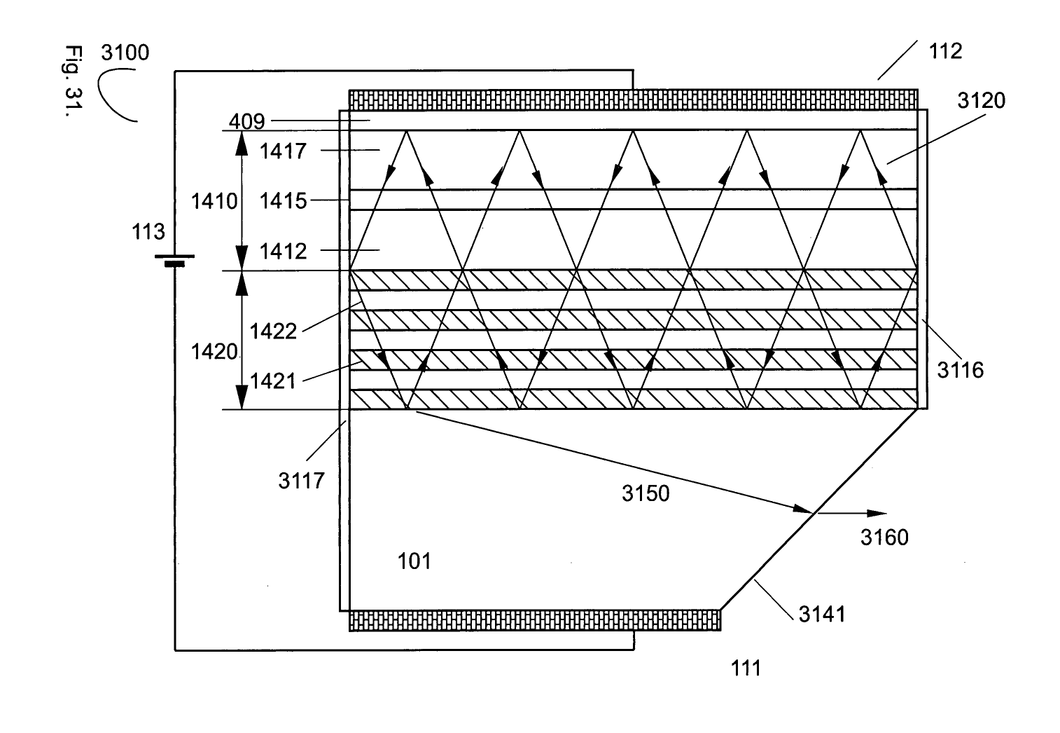

FIG. 31 shows yet another embodiment of the present invention, where a tilted cavity laser (3100) is designed such that the laser light in the resonant optical mode (3120) undergoes total internal reflection at both the antireflecting coating (3116) at the front facet and the high reflection coating (3117) at the rear facet. The light in the resonant optical mode leaks into the substrate (3150). At least one of the side surfaces of the substrate is cut (3141) at a tilt angle. By varying the angle of the tilt cut (3141), one may control the direction of propagation of the light (3160) coming out of the structure. It is possible to direct the light (3160), for example, parallel to the top substrate surface or at any other angle.

In yet another embodiment, the light output through a leaky mode is realized in an optical amplifier.

In another embodiment, a resonant photodetector operates, when light comes through a broad aperture at the side substrate surface and is resonantly coupled with a tilted mode within a cavity.

In yet another embodiment, a light-emitting device is fabricated, where a plurality of tilted optical modes leak into the substrate and come out through a side surface of the substrate.

In another embodiment, the light-emitting device is fabricated such that a plurality of tilted optical modes leak into the substrate and come out through a tilted cut of the side substrate surface.

In another embodiment of the present invention, the active region of a tilted cavity laser includes a few quantum wells, or a few layers of quantum wires or quantum dots, or any combination thereof. The layers are designed such that different layers have material gain spectra centered at different wavelengths, thus the whole active region has a broad material gain spectrum, which additionally enhances the stabilization of the wavelength of laser radiation.

In another embodiment of the present invention, the structure providing a high selectivity in losses of the tilted optical modes is used as an optical amplifier or a resonant photodetector.

In any embodiment having a light-emitting diode, a semiconductor diode laser, an optical amplifier, or a resonant photodetector, a plurality of preferable semiconductor materials can be used to realize the present invention.

In some embodiments, the layers of the semiconductor device are formed of materials including, but not limited to, GaN, AlN, InN, and any alloys based on these materials. The n-doped layers are formed by using a doping impurity, which includes, but is not limited to Si or Sn, where the technology is selected such that these impurities are preferably incorporated into the cation sublattice. The p-doped layers are formed by using a p-doping impurities, which include but are not limited to Be and Mg.

In some other embodiments, the layers of the semiconductor device are formed of materials including, but not limited to, GaAs and GaAlAs alloys.

Mode-Locked Tilted Cavity Laser

If the resonant optical mode generated by a tilted cavity laser has a small tilt angle θ with respect to the direction normal to the p-n junction plane, the effective velocity of the propagation of light in the p-n junction plane is reduced with respect to the velocity of propagation in the homogeneous medium approximately by a factor of sin θ, as discussed above.

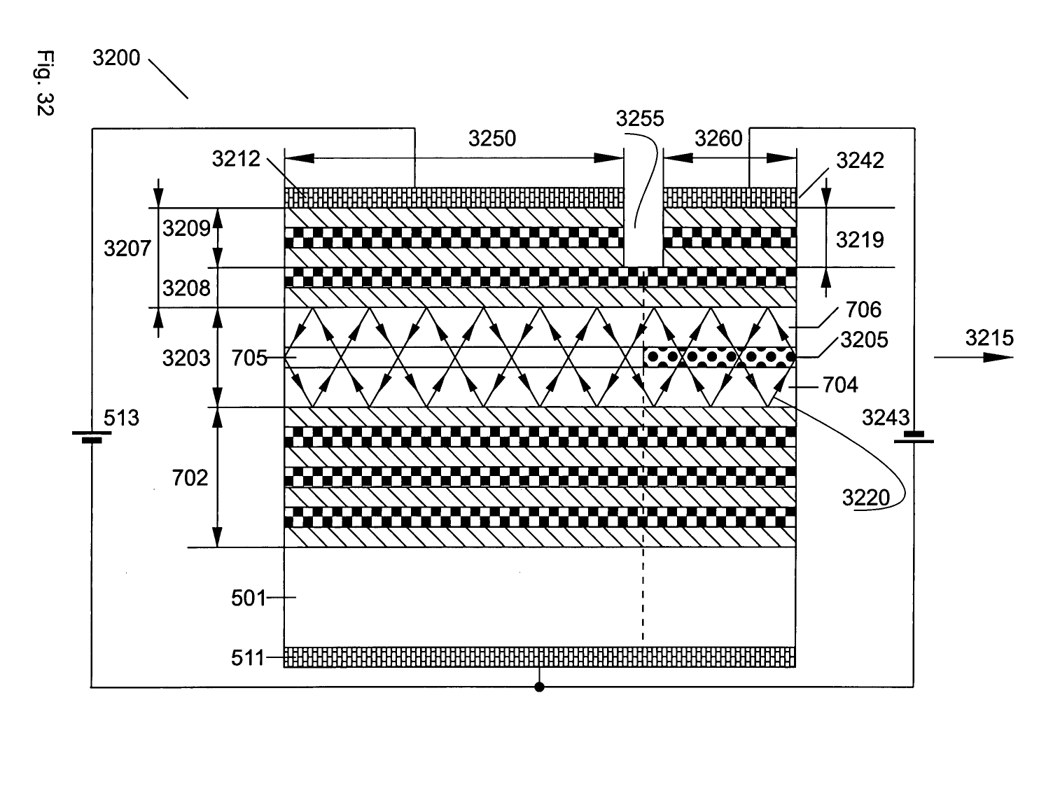

The reduction of the velocity of propagation of the light in the direction of the p-n junction plane for tilted cavity lasers is used in mode-locked lasers to reduce the repetition frequency. FIG. 32 shows a schematic diagram of a mode-locked tilted cavity laser in an embodiment of the present invention. A tilted optical mode (3220) is generated in the laser (3200). The laser (3200) includes an active section (3250) operating under a forward bias (513) and a passive section (3260) operating under a reverse bias (3243) or under zero bias and acting as a saturable light absorber. The forward bias (513) is applied to the active section (3250) through the bottom contact (511) and the first top contact (3212). The reverse bias (3243) is applied to the passive section (3260), electrically separated by etching and (or) ion implantation from the active session, through the bottom contact (511) and the second top contact (3242). The top multilayered interference reflector (3207) is etched to separate the paths of current spreading in the active and passive sections. Part of the top mirror (3208) is common to both sections, while the multilayered structures (3209) and (3219) are separated by a trench (3255). The cavity (3203) includes an n-doped layer (704) and a layer, which operates as an active layer (705) generating light in the active section (3250), and which operates as an absorbing layer (3205) in the passive section (3260). Light comes out (3215) of the mode-locked tilted cavity laser in the form of pulses. The repetition frequency depends on the length of the stripe and the group velocity of propagation of the light in the direction along the stripe. The stripe length is defined by the geometrical distance between the two facets, and for FIG. 32 equals the aggregated lengths of the sections (3250), (3255) and (3260). Use of a mode-locked tilted cavity laser allows a technologically important repetition frequency of 1 GHz to 7 GHz for a conventional stripe length of about 500 μm.

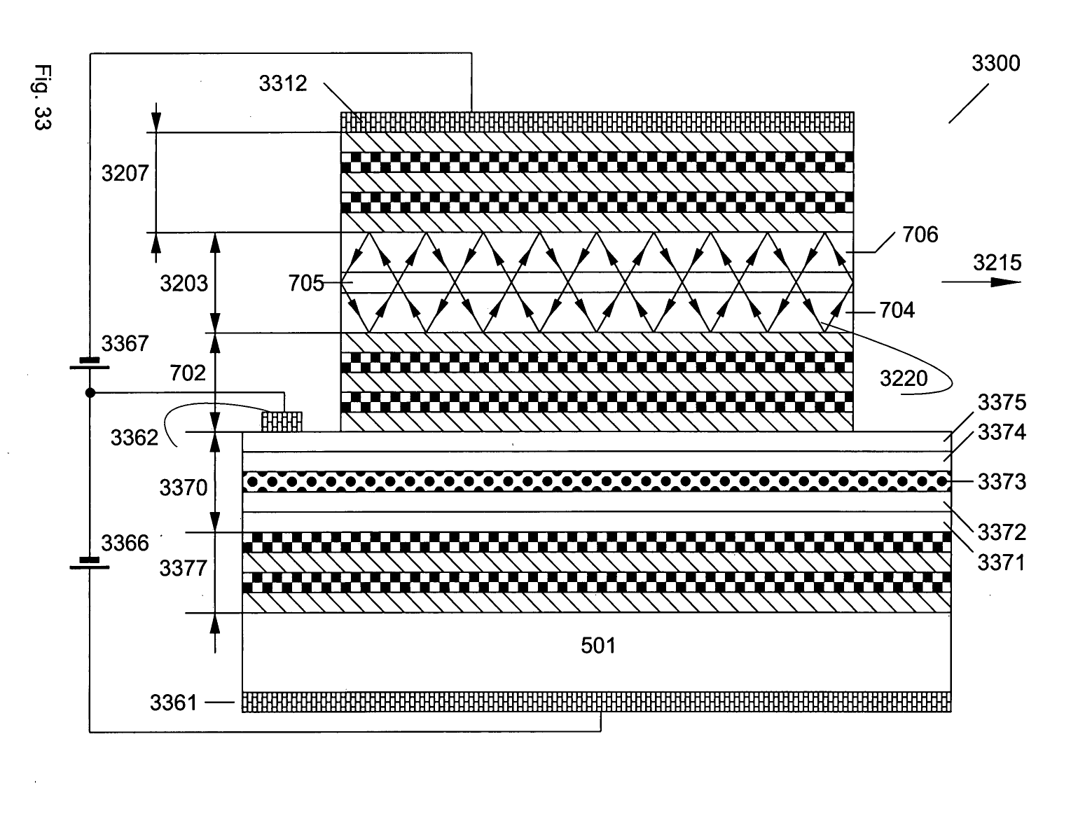

FIG. 33 shows a schematic diagram of a tilted cavity mode-locked laser (3300) according to another embodiment of the present invention. The tilted cavity includes a substrate (501), a first MIR (3377), an absorbing element (3370), a second MIR (702), a tilted cavity (3203), and a third MIR (3207). The absorbing element (3370) preferably includes an n-doped layer (3371), a weakly n-doped or an undoped layer (3372), an absorbing region (3373), a weakly p-doped or an undoped region (3374), and a p-doped current spreading layer (3375). An n-contact (3361) is mounted at the substrate (501) from the side opposite to the first MIR (3377). An intracavity p-contact (3362) is mounted at the current spreading layer (3375). An n-contact (3312) is mounted atop the third MIR (3207). The p-n junction for a laser placed within the layer (705) within the tilted cavity (3203) operates under a forward bias (3367) and generates light. The saturable absorber layer (3373) contains a p-n junction, which operates under a reverse bias (3366). In particular, this p-n junction is preferably a bulk-like layer, one or more quantum wells, one or more layers of quantum wires or quantum dots, one or more double heterostructures, and any combination thereof, providing efficient absorption of the lasing emission and acting as a saturable absorber. Then with zero bias or under a reverse bias, the p-n junction absorbs light. The first MIR (3377), the second MIR (702), the third MIR (3207), and the tilted cavity (3203) are optimized such that the laser light in the resonant tilted optical mode reaches the absorbing layer (3373) with sufficient intensity such that the device operates as a mode-locked laser.

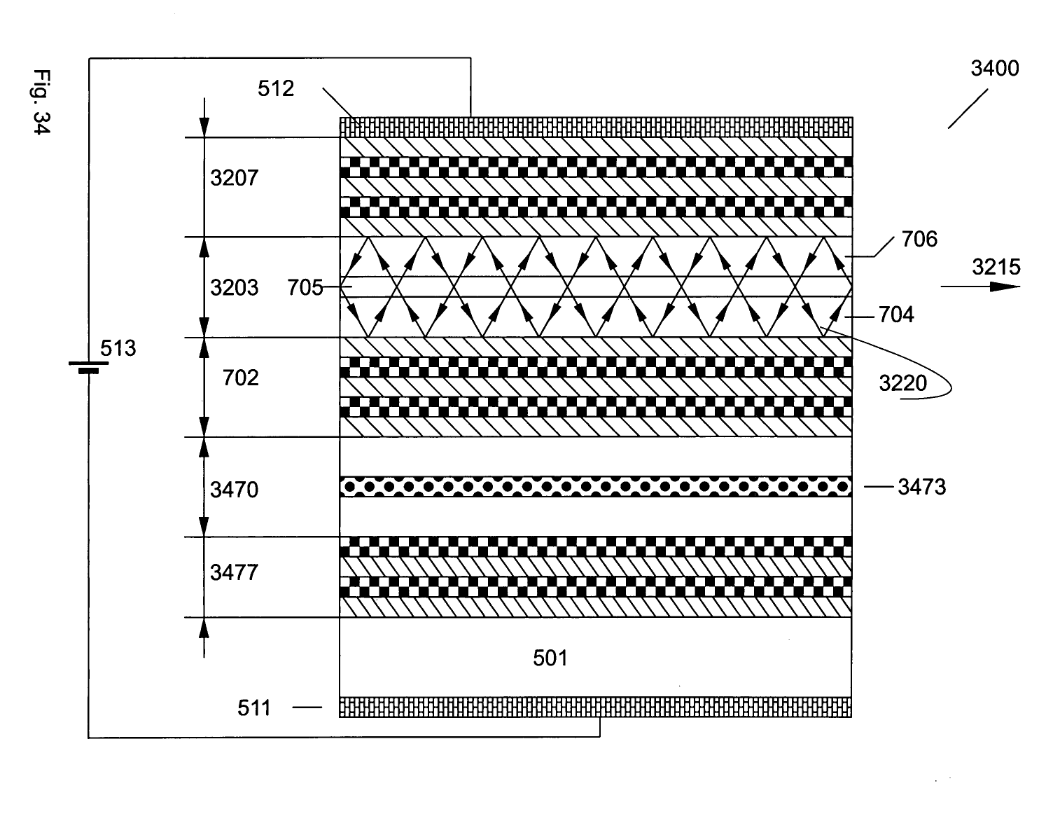

In another embodiment, only two contacts are used in the structure and the saturable absorption effect is achieved in the passive cavity by intentional introduction of narrow bandgap semiconductor material absorbing light at the wavelength emitted by the laser and defects to ensure fast depopulation of the excited electronic states of the absorbing medium due to non-radiative recombination. This may occur if the layer is formed of a narrow gap plastically relaxed (metamorphic) material, i.e. a material having a different lattice constant than the substrate, where defects such as dislocations or point defects are generated. Examples of the layer include, but are not limited to, i) a plastically relaxed (dislocated) GaInAs layer of high-enough indium composition, ii) a narrow bandgap material grown at a low growth temperature, such as low-temperature grown GaInAs, iii) a wider bandgap low-temperature grown layer such as GaAs, which contains a high concentration of metallic arsenic nanoclusters providing strong local absorption of light by interface states, iv) narrow gap dislocated quantum dots or quantum wires made of narrow gap material, or any combinations thereof. FIG. 34 shows schematically a tilted cavity mode-locked laser (3400) according to this embodiment. The structure preferably includes an n-doped substrate (501), an n-doped first MIR (3477), an n-doped passive cavity (3470), in which a saturable absorber layer (3473) is inserted, an n-doped second MIR (702), an active cavity (3203), and a p-doped third MIR (3207). The active cavity (3203) includes an n-doped layer (704), an active region (705), and a p-doped layer (706).

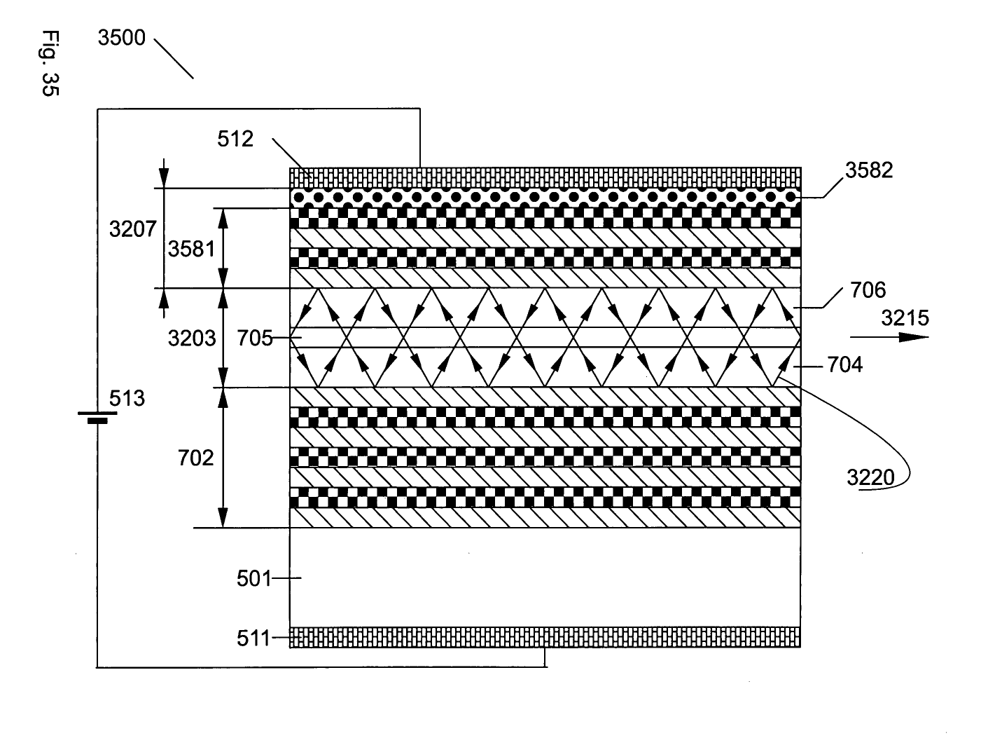

FIG. 35 shows schematically a tilted cavity mode-locked laser (3500) according to another embodiment of the present invention. An absorbing layer (3582) is placed between the transparent part of the top MIR (3581) and the p-contact (512). High absorption of the lasing emission in a layer (3582) is achieved, for example, if this layer has a bandgap low enough to absorb laser emission, and, additionally, contains a high density of defects or a high density of surface states responsible for nonradiative recombination to ensure depopulation. This may occur if the layer is formed from a material including, but not limited to, a narrow gap metamorphic material with a high concentration of dislocations, a narrow bandgap material grown at a low growth temperature, such as low-temperature grown GaInAs, a wider bandgap low-temperature layer containing high-concentration of metallic arsenic nanoclusters providing local absorption by interface states, narrow gap quantum dots or quantum wires made of narrow gap material, or by combinations of any of the above materials.

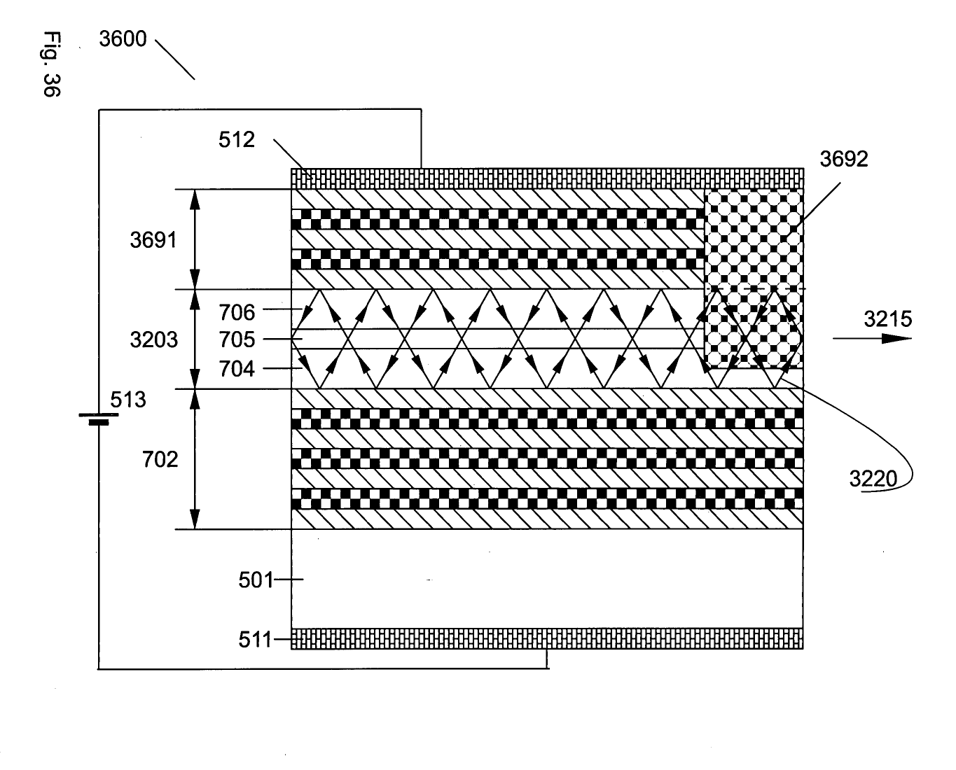

FIG. 36 shows schematically a tilted cavity mode-locked laser (3600) according to another embodiment of the present invention. A tilted optical mode (3220) is generated in the laser (3600). A defect region (3692) forming an absorbing section of the laser is formed by ion implantation, wherein the defect region is expanded through the top MIR (3691), the player (706) of the active cavity (3203), the active region (705) and partially the n-layer (704) of the active cavity.

Tilted Cavity Laser with a Double Tilt

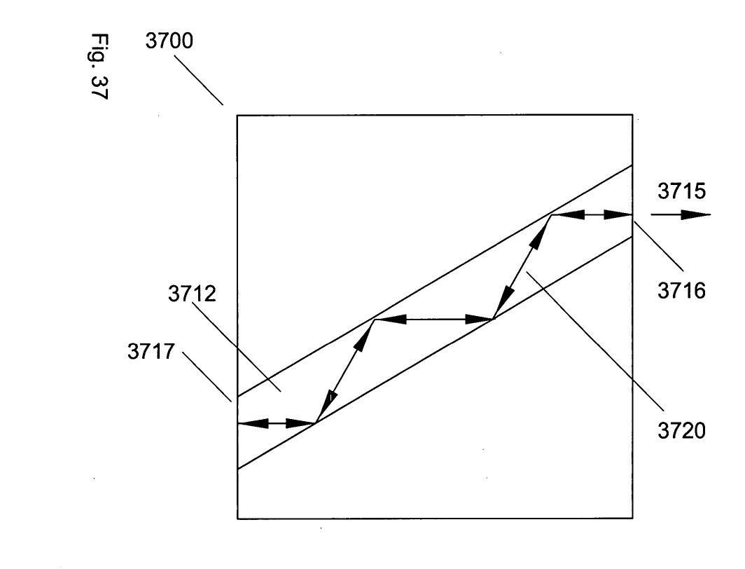

FIG. 37 shows schematically a top view of a tilted cavity laser (3700) where the stripe forming a top contact (3712) is rotated in the lateral plane such that it forms an angle with the front facet (3716) and the rear facet (3717) different from 90 degrees. Then the feedback occurs only for tilted optical modes (3720), wherein the direction of propagation of light is additionally tilted in the lateral plane. Thus, the resonant optical mode is twice tilted, first in the vertical plane, and second in the lateral plane. An additional tilt of the optical path of the resonant optical mode results in an additional slowing down of the propagation of light within a tilted cavity laser. The laser light in a twice tilted optical mode (3720) comes out (3715) through the front facet (3716).

Tilted Cavity Optical Amplifier with a Weak Polarization Sensitivity

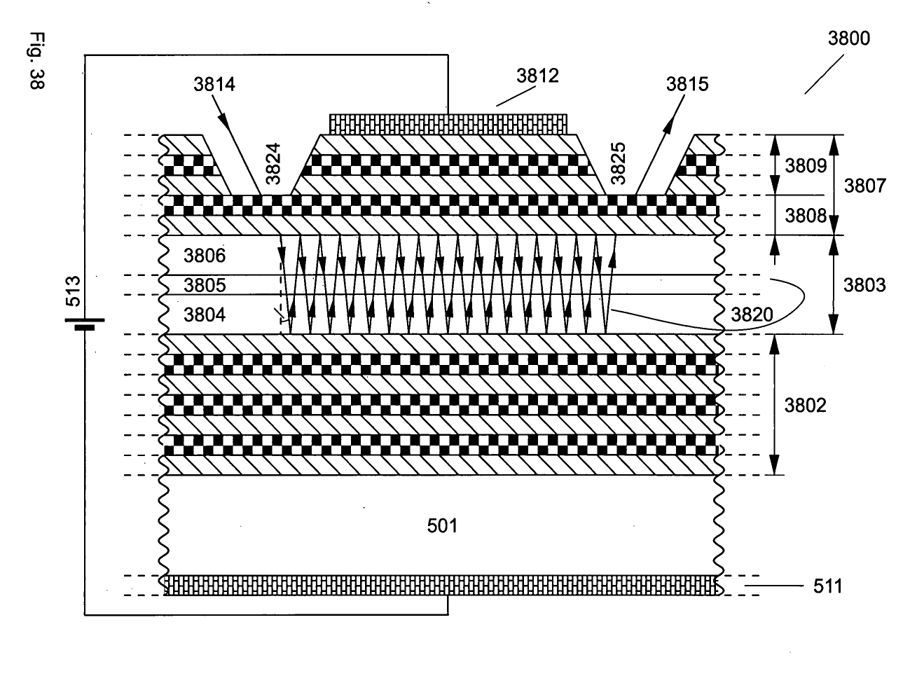

FIG. 38 shows schematically a tilted cavity optical amplifier according to another embodiment of the present invention. The optical amplifier (3800) preferably includes an n-doped substrate (501), an n-doped bottom multilayered interference reflector (MIR) (3802), a tilted cavity (3803), and a p-doped top MIR (3807). The tilted cavity (3803) preferably comprises an n-doped layer (3804), an active region (3805), and a p-doped layer (3806). The top MIR (3807) is selectively etched such that two trenches (3824) and (3825) are formed. A few layers of the top MIR (3807) are not etched and form a continuous part (3808) of the MIR. The rest of the layers (3809) are broken by two trenches (3824) and (3825). An n-contact (511) is preferably mounted on the substrate (501) on the side opposite to the bottom MIR (3802). A p-contact (3812) is mounted atop the top MIR (3807) preferably between the two trenches (3824) and (3825). A forward bias (513) is applied to the active region (3805) via the n-contact (511) and the p-contact (3812).

The active region (3805) generates optical gain when a forward bias (513) is applied. The input light (3814) comes through a first trench (3824) into the structure, propagates along the tilted cavity (3803) in a form of the tilted optical mode (3820), is enhanced, and comes out (3815) through the second trench (3825). The tilted cavity (3803), the bottom MIR (3802), and the top MIR (3807) are designed such that the amplification rate is wavelength-selective, and the maximum amplification rate is realized for optical modes at a certain wavelength, and propagating within a cavity as a tilted optical mode at a small tilt angle s between the direction of propagation and the direction normal to the p-n junction plane. For such a small angle, the difference between TE and TM optical modes is minor, and the optical modes with two polarizations behave similarly. In particular, the amplification rate will be close for the light of two different polarizations. Such a device may operate as a nearly polarization-insensitive resonant optical amplifier.

Although the invention has been illustrated and described with respect to exemplary embodiments thereof, it should be understood by those skilled in the art that the foregoing and various other changes, omissions and additions may be made therein and thereto, without departing from the spirit and scope of the present invention. Therefore, the present invention should not be understood as limited to the specific embodiments set out above but to include all possible embodiments which are embodied within a scope encompassed and equivalents thereof with respect to the features set out in the appended claims. Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

1. A semiconductor wavelength-selective tilted cavity light-emitting diode comprising:
a) a substrate;
b) a top coating;
c) a cavity comprising a p-n junction element and located between the top coating and the substrate wherein the p-n junction element is an active element which generates light when a forward bias is applied; and
d) a bottom mirror located between the cavity and the substrate;
wherein a direction of propagation of light within the p-n junction element and a direction normal to a plane of the p-n junction form a tilt angle; and
wherein the cavity, the bottom mirror, and the top coating are designed such that a transmission of generated optical power within a spectral range and within an interval of tilt angles through the bottom mirror to the substrate is minimized, and the transmission of generated optical power through the top coating within the same or a broader spectral range and within the same interval of tilt angles is optimized to achieve a required output power level.

2. The light-emitting diode of claim 1, wherein the light-emitting diode operates as a superluminescent light-emitting diode.

3. The light-emitting diode of claim 2, wherein the top coating comprises a top multilayered structure.

4. The light-emitting diode of claim 3, wherein the top multilayered structure is a multilayered interference reflector.

5. The light-emitting diode of claim 2, wherein the bottom mirror comprises a bottom multilayered structure.

6. The light-emitting diode of claim 5, wherein the top coating comprises a top multilayered structure.

7. The light-emitting diode of claim 5, wherein the bottom mutlilayered structure is a multilayered interference reflector.

8. The light-emitting diode of claim 7, wherein the top mirror comprises a top multilayered structure.

9. The light-emitting diode of claim 8, wherein the top multilayered structure is a top multilayered interference reflector.

10. The light-emitting diode of claim 9, wherein the cavity further comprises an antiwaveguiding cavity, wherein an average refractive index of the antiwaveguiding cavity is lower than an average refractive index of the bottom multilayered interference reflector and lower than an average refractive index of the top multilayered interference reflector, where the average refractive index of each multilayered interference reflector is defined as a square root of a weighted average of a square of the refractive indices of the constituent layers.

11. The light-emitting diode of claim 10, wherein the cavity, the bottom multilayered interference reflector, and the top multilayered interference reflector are designed such that a confinement factor of one transverse optical mode within the active element exceeds a confinement factor of each other transverse optical mode within the active element by at least a factor of five.

12. The light-emitting diode of claim 11, wherein an emission of light occurs in a single transverse optical mode.

13. The light-emitting diode of claim 5, further comprising a rear facet obtained by cleavage or etching of the substrate, the bottom mirror, the cavity, and the top coating, wherein the rear facet is tilted with respect to a substrate surface at an angle not equal to 90°.

14. The light-emitting diode of claim 5, wherein the top mirror comprises a top multilayered structure.

15. The light-emitting diode of claim 5, further comprising a front facet obtained by cleavage or etching of the substrate, the bottom mirror, the cavity, and the top coating, wherein the front facet is tilted with respect to a substrate surface at a first angle not equal to 90°.

16. The light-emitting diode of claim 15, further comprising a rear facet obtained by cleavage or etching of the substrate, the bottom mirror, the cavity, and the top coating, wherein the rear facet is tilted with respect to a substrate surface at a second angle not equal to 90°.

17. The light-emitting diode of claim 16, wherein a cross-section of the epitaxially grown structure has a shape of a trapezoid.

18. The light-emitting diode of claim 16, wherein a cross-section of the epitaxially grown structure has a shape of a parallelogram.

19. The light-emitting diode of claim 16, wherein the bottom mirror and the top coating are designed to reflect maximum optical power back to the cavity.

20. The light-emitting diode of claim 19, wherein the first angle and the second angle are chosen to provide a maximum output of optical power through the front facet.

21. The light-emitting diode of claim 1, wherein at least a portion of the diode is formed of a first material selected from the group consisting of:
a) a III-V semiconductor material; and
b) an alloy of at least two III-V semiconductor materials.

22. The light-emitting diode of claim 21, wherein the light-emitting diode operates as a superluminescent light-emitting diode.

23. The light-emitting diode of claim 22, wherein the bottom mirror comprises a bottom multilayered structure.

24. The light-emitting diode of claim 22, wherein the top coating comprises a top multilayered structure.

25. The light-emitting diode of claim 24, wherein the bottom mirror comprises a bottom multilayered structure.

26. The light-emitting diode of claim 21, wherein the first material is a binary compound comprising a first element and a second element;
wherein the first element is selected from the group consisting of:
i) Al;
ii) Ga; and
iii) In;
and the second element is selected from the group consisting of:
i) N;
ii) P;
iii) As; and
iv) Sb.

27. The light-emitting diode of claim 26, wherein the light-emitting diode operates as a superluminescent light-emitting diode.

28. The light-emitting diode of claim 21, wherein at least a portion of the diode is formed of a second material selected from the group consisting of:
a) AlN
b) GaN;
c) InN; and
d) an alloy of materials selected from the group consisting of AlN; GaN; and InN.

29. The light-emitting diode of claim 28, wherein the light-emitting diode operates as a superluminescent light-emitting diode.

30. The light-emitting diode of claim 21, wherein the bottom mirror comprises a bottom multilayered structure.

31. The light-emitting diode of claim 21, wherein the top coating comprises a top multilayered structure.

32. The light-emitting diode of claim 31, wherein the bottom mirror comprises a bottom multilayered structure.

33. The light-emitting diode of claim 31, further comprising a rear facet obtained by cleavage or etching of the substrate, the bottom mirror, the cavity, and the top coating, wherein the rear facet is tilted with respect to a substrate surface at an angle not equal to 90°.

34. The light-emitting diode of claim 1, wherein the bottom mirror comprises a bottom multilayered structure.

35. The light-emitting diode of claim 33, wherein the top coating comprises a top multilayered structure.

36. The light-emitting diode of claim 34, wherein the top mirror comprises a top multilayered structure.

37. The light-emitting diode of claim 1, wherein the top coating comprises a top multilayered structure.

38. The light-emitting diode of claim 37, wherein the top multilayered structure is a top multilayered interference reflector.

39. The light-emitting diode of claim 34, wherein the bottom mutlilayered structure is a multilayered interference reflector.

40. The light-emitting diode of claim 39, wherein the top mirror comprises a top multilayered structure.

41. The light-emitting diode of claim 40, wherein the top multilayered structure is a top multilayered interference reflector.

42. The light-emitting diode of claim 41, wherein the cavity further comprises an antiwaveguiding cavity, wherein an average refractive index of the antiwaveguiding cavity is lower than an average refractive index of the bottom multilayered interference reflector and lower than an average refractive index of the top multilayered interference reflector, where the average refractive index of each multilayered interference reflector is defined as a square root of a weighted average of a square of the refractive indices of the constituent layers.

43. The light-emitting diode of claim 42, wherein the cavity, the bottom multilayered interference reflector, and the top multilayered interference reflector are designed such that a confinement factor of one transverse optical mode within the active element exceeds a confinement factor of each other transverse optical mode within the active element by at least a factor of five.

44. The light-emitting diode of claim 43, wherein an emission of light occurs in a single transverse optical mode.

45. The light-emitting diode of claim 1, further comprising a front facet obtained by cleavage or etching of the substrate, the bottom mirror, the cavity, and the top coating, wherein the front facet is tilted with respect to a substrate surface at a first angle not equal to 90°.

46. The light-emitting diode of claim 45, further comprising a rear facet obtained by cleavage or etching of the substrate, the bottom mirror, the cavity, and the top coating, wherein the rear facet is tilted with respect to a substrate surface at a second angle not equal to 90°.

47. The light-emitting diode of claim 46, wherein a cross-section of the epitaxially grown structure has a shape of a trapezoid.

48. The light-emitting diode of claim 46, wherein a cross-section of the epitaxially grown structure has a shape of a parallelogram.

49. The light-emitting diode of claim 46, wherein the bottom mirror and the top coating are designed to reflect maximum optical power back to the cavity.

50. The light-emitting diode of claim 49, wherein the first angle and the second angle are chosen to provide a maximum output of optical power through the front facet.

51. A light-emitting system comprising:
a) a phosphorous-containing medium;
b) an external mirror; and
c) a semiconductor tilted cavity light-emitting diode comprising:
i) a substrate;
ii) a top coating;
iii) a cavity comprising a p-n junction element and located between the top coating and the substrate wherein the p-n junction element is an active element which generates light when a forward bias is applied; and
iv) a bottom mirror located between the cavity and the substrate;
wherein a direction of propagation of light within the p-n junction element and a direction normal to the plane of the p-n junction form a tilt angle;
wherein the diode is designed to emit light in an ultraviolet spectral region;
wherein the phosphorous-containing medium, which is located between the diode and the external mirror, partially absorbs light in the ultraviolet spectral region, and emits visible light due to photoluminescence; and
wherein the external mirror is semi-transparent to visible light and is non-transparent to light in the ultraviolet spectral region.

52. The light-emitting system of claim 51, wherein the cavity, the bottom mirror, and the top coating are designed such that a transmission of generated optical power within a spectral range and within an interval of tilt angles through the bottom mirror to the substrate is minimized, and the transmission of generated optical power through the top coating within the same or a broader spectral range and within the same interval of tilt angles is optimized to achieve a required output power level.

53. The light-emitting system of claim 51, wherein the light-emitting diode operates as a superluminescent light-emitting diode.

54. The light-emitting system of claim 53, wherein the top coating comprises a top multilayered structure.

55. The light-emitting system of claim 53, wherein the bottom mirror comprises a bottom multilayered structure.

56. The light-emitting system of claim 53, wherein at least a portion of the superluminescent light-emitting diode is composed of a material selected from the group consisting of:
a) AlN;
b) GaN;
c) InN; and
d) an alloy of materials selected from the group consisting of AlN; GaN; and InN.

57. The light-emitting system of claim 51, wherein the top coating comprises a top multilayered structure.

58. The light-emitting system of claim 51, wherein the bottom mirror comprises a bottom multilayered structure.

59. The light-emitting system of claim 51, wherein at least a portion of the diode is composed of a material selected from the group consisting of:
a) AlN;
b) GaN;
c) InN; and
d) an alloy of materials selected from the group consisting of AlN; GaN; and InN.

60. A light-emitting system comprising:
a) an external mirror; and
b) a tilted cavity semiconductor laser comprising:
i) a substrate;
ii) a bottom mirror contiguous with the substrate wherein the bottom mirror is a multilayered interference reflector;
iii) a cavity comprising a p-n junction element and contiguous with the bottom mirror on a side opposite the substrate wherein the p-n junction element is an active element which generates light when a forward bias is applied; and
iv) a top mirror contiguous with the cavity from a side opposite to the bottom mirror wherein the top mirror is a multilayered interference reflector;
wherein a direction of propagation of light within the p-n junction element and a direction normal to the junction plane forms a tilt angle.

61. The light-emitting system of claim 60, wherein the cavity, the bottom mirror, and the top mirror are designed such that:
A) the tilt angle of the resonant tilted optical mode is smaller than an angle of total internal reflectance at a semiconductor/air interface;
B) the top mirror is partially etched to allow the output of generated laser light through the top mirror;
C) the external mirror is semi-transparent for generated laser light;
D) the external mirror is placed such that generated laser light coming out through the top mirror is partially reflected from the external mirror and comes back to the cavity thus providing an additional feedback for the generated laser light; and
E) the additional feedback provides additional stabilization of the wavelength of laser radiation.

62. A semiconductor tilted cavity laser comprising:
a) a substrate;
b) a top mirror;
c) a cavity comprising a p-n junction element and located between the top mirror and the substrate wherein the p-n junction element is an active element which generates light when a forward bias is applied;
d) a bottom mirror located between the cavity and the substrate;
e) a front facet obtained by cleavage or etching of the substrate, the bottom mirror, the cavity and the top mirror; and
f) a rear facet obtained by cleavage or etching of the substrate, the bottom mirror, the cavity, and the top mirror;
wherein the front facet or the rear facet is tilted with respect to a substrate surface at a tilt angle not equal to 90°;
wherein a direction of propagation of light within the p-n junction element and the direction normal to the junction plane forms a tilt angle.

63. The tilted-cavity laser of claim 62, wherein the bottom mirror is a bottom multilayered interference reflector and the top mirror is a top multilayered interference reflector.

64. The tilted-cavity laser of claim 62, wherein the front facet is tilted with respect to the substrate surface at a first angle not equal to 90° and the rear facet is tilted with respect to the substrate surface at a second angle not equal to 90°.

65. The tilted-cavity laser of claim 64, wherein the cross-section of the epitaxially grown structure has a shape of a trapezoid.

66. The tilted-cavity laser of claim 64, wherein the cross-section of the epitaxially grown structure has a shape of a parallelogram.

67. The tilted-cavity laser of claim 64, wherein the cavity, the top mirror, the bottom mirror, and the tilt angle of the at least one facet are designed such that a positive feedback exists for one tilted optical mode, which propagates normally to the front facet and to the rear facet.

68. A mode-locked tilted cavity laser comprising:
a) a substrate;
b) a bottom multilayered interference reflector contiguous with the substrate;
c) a cavity comprising at least one p-n junction element and contiguous with the bottom multilayered interference reflector on a side opposite the substrate wherein the p-n junction element comprises at least a first element section and a second element section, wherein the first element section includes an active element which generates light when a forward bias is applied and the second element section includes an absorber which absorbs light when a reverse bias is applied;
d) a top multilayered interference reflector contiguous with the cavity on a side opposite the bottom multilayered interference reflector, wherein the top multilayered interference reflector is partially etched such that it comprises a first top reflector section and a second top reflector section;
e) a first p-contact mounted on the first top reflector section on a side opposite the cavity;
f) a second p-contact mounted on the second top reflector section on a side opposite the cavity; and
g) an n-contact mounted on the substrate on a side opposite the bottom multilayered interference reflector;
wherein a direction of propagation of light within the p-n junction element and the direction normal to the junction plane forms a tilt angle;
wherein a forward bias is applied between the first p-contact and the n-contact; and
wherein a reverse bias is applied between the second p-contact and the n-contact.

69. The mode-locked tilted cavity laser of claim 68, wherein the cavity, the bottom multilayered interference reflector, and the top multilayered interference reflector are designed such that a resonant optical mode, having a certain wavelength and propagating at a certain tilt angle, has a first absolute value of the electric field strength at the p-n junction element, and any optical modes at a different wavelength or propagating at a different angle have a second absolute value of the electric field strength at the p-n junction element, wherein the second absolute value is smaller than the first absolute value of the resonant optical mode.

70. The mode-locked tilted cavity laser of claim 68, wherein the cavity, the bottom multilayered interference reflector, and the top multilayered interference reflector are designed such that a resonant optical mode, having a certain wavelength and propagating at a certain tilt angle, has a first value of the leakage losses to the substrate and to at least one contact layer, and any optical modes at a different wavelength or propagating at a different angle have a second value of the leakage losses to the substrate and to at least one contact layer, wherein the second value is larger than the first value of the resonant optical mode.

71. A mode-locked tilted cavity laser comprising:
a) a substrate;
b) a first multilayered interference reflector contiguous with the substrate;
c) an absorbing element contiguous with the first multilayered interference reflector on a side opposite the substrate;
d) a second multilayer intereference reflector contiguous with the absorbing element on a side opposite the first multilayered interference reflector;
e) a cavity contiguous with the second multilayered interference reflector on a side opposite the absorbing element;
f) a third multilayered interference reflector contiguous with the cavity on a side opposite the second multilayered interference reflector;
g) a first contact contiguous with the substrate on a side opposite the first multilayered interference reflector;
h) a second contact mounted as an intracavity contact and contiguous with the absorbing element on a side opposite the first multilayered interference reflector;
i) a third contact placed with respect to the third multilayered interference reflector on a side opposite the cavity;
j) a first p-n junction element placed within the absorbing element;
k) at least one second p-n junction element placed within an element selected from the group consisting of:
i) the second multilayered interference reflector;
ii) the cavity;
iii) the third multilayered interference reflector; and
iv) any combination of i) through iii);
l) a first bias element between the first contact and the second contact providing a reverse bias at the first p-n junction element; and
m) a second bias element between the second contact and the third contact providing a forward bias at the first p-n junction element;
wherein a direction of propagation of light within the p-n junction element and the direction normal to the junction plane forms a tilt angle.

72. The tilted cavity laser of claim 71, wherein the cavity, the first multilayer intereference reflector, the second multilayered interference reflector, and the third multilayered interference reflector are optimized such that a resonant optical mode, having a certain wavelength and propagating at a certain tilt angle, has a first absolute value of the electric field strength at the second p-n junction element, and any optical modes at a different wavelength or propagating at a different angle have a second absolute value of the electric field strength at the second p-n junction element, wherein the second absolute value is smaller than the first absolute value of the resonant optical mode.

73. The tilted cavity laser of claim 71, wherein the cavity, the first multilayer intereference reflector, the second multilayered interference reflector, and the third multilayered interference reflector are optimized such that a resonant optical mode, having a certain wavelength and propagating at a certain tilt angle, has a first value of the leakage losses to the substrate and to at least one contact layer, and any optical modes at a different wavelength or propagating at a different angle have a second value of the leakage losses to the substrate and to at least one contact layer, wherein the second value is larger than the first value of the resonant optical mode.

74. The tilted cavity laser of claim 71, wherein the second multilayered interference reflector is optimized such that an electric field strength of the resonant optical mode within the absorbing element provides a bleaching effect.

75. A mode-locked tilted cavity laser comprising:
a) a substrate;
b) a bottom multilayered interference reflector contiguous with the substrate;
c) a cavity contiguous with the bottom multilayered interference reflector on a side opposite the substrate;
d) a top multilayered interference reflector contiguous with the cavity on a side opposite the bottom multilayered interference reflector;
e) an absorbing element contiguous with the top multilayered interference reflector on a side opposite the cavity;
f) a bottom contact contiguous with the substrate on a side opposite the bottom multilayered interference reflector;
g) a top contact contiguous with the absorbing element on a side opposite the top multilayered interference reflector;
h) at least one p-n junction element placed within an element selected from the group consisting of:
i) the bottom multilayered interference reflector;
ii) the cavity;
iii) a top multilayered interference reflector; and
iv) any combination of i) through iii) above;
i) a bias element between the bottom contact and the top contact that provides a forward bias to a p-n junction within the p-n junction element;
wherein the absorbing element comprises a high density of defects which enable non-radiative recombination of electron-hole pairs and is selected from the group consisting of:
i) a metamorphic layer obtained via lattice-mismatched growth and containing a high density of extended or point defects;
ii) a layer containing dislocated quantum dots;
iii) a layer containing dislocated quantum wires;
iv) a layer grown at a low temperature;
v) a layer containing metallic precipitates; and
vi) any combination of i) through v).

76. A mode-locked tilted cavity laser comprising:
a) a substrate;
b) a bottom multilayered interference reflector contiguous with the substrate;
c) a cavity comprising at least one p-n junction element and contiguous with the bottom multilayered interference reflector on a side opposite the substrate wherein the p-n junction element comprises:
i) a first element section including an active element which generates light when a forward bias is applied; and
ii) a second element section including an absorber which absorbs light when a reverse bias is applied;
d) a top multilayered interference reflector contiguous with the cavity on a side opposite the bottom multilayered interference reflector, wherein the top multilayered interference reflector is partially etched such that it comprises a first top reflector section and a second top reflector section;
wherein a direction of propagation of light within the p-n junction element and a direction normal to the junction plane forms a tilt angle;
e) a first p-contact mounted on the first top reflector section on a side opposite the cavity;
f) a second p-contact mounted on the second top reflector section on a side opposite the cavity; and
g) an n-contact mounted on the substrate on a side opposite the bottom multilayered interference reflector;
wherein a forward bias is applied between the first p-contact and the n-contact; and
wherein a reverse bias is applied between the second p-contact and the n-contact.

77. The mode-locked tilted cavity laser of claim 76, wherein the cavity, the bottom multilayered interference reflector, and the top multilayered interference reflector are designed such that a resonant optical mode, having a certain wavelength and propagating at a certain tilt angle, has a first value of the leakage losses out of the cavity into the substrate and to at least one contact layer, and any optical modes at a different wavelength or propagating at a different angle have a second value of the leakage losses into the substrate and to at least one contact layer, wherein the second value is larger than the first value for the resonant optical mode.

78. The mode-locked tilted cavity laser of claim 76, wherein the cavity, the bottom multilayered interference reflector, and the top multilayered interference reflector are designed such that a resonant optical mode, having a certain wavelength and propagating at a certain tilt angle, has a first absolute value of the electric field strength at the p-n junction element, and any optical modes at a different wavelength or propagating at a different angle have a second absolute value of the electric field strength at the p-n junction element, wherein the second value is smaller than the first value for the resonant optical mode.

79. A mode-locked tilted cavity laser comprising:
a) a substrate;
b) a first multilayered interference reflector contiguous with the substrate;
c) an absorbing element contiguous with the first multilayered interference reflector on a side opposite the substrate;
d) a second multilayer intereference reflector contiguous with the absorbing element on a side opposite the first multilayered interference reflector;
e) a cavity contiguous with the second multilayered interference reflector on a side opposite the absorbing element;
f) a third multilayered interference reflector contiguous with the cavity on a side opposite the second multilayered interference reflector;
g) a first contact contiguous with the substrate on a side opposite the first multilayered interference reflector;
h) a second contact mounted as an intracavity contact and contiguous with the absorbing element on a side opposite the first multilayered interference reflector;
i) a third contact placed with respect to the third multilayered interference reflector on a side opposite the cavity;
j) a first p-n junction element placed within the absorbing element;
k) a second p-n junction element placed within an element selected from the group consisting of:
i) the second multilayered interference reflector;
ii) the cavity;
iii) the third multilayered interference reflector; and
iv) any combination of i) through iii);
l) a first bias element between the first contact and the second contact, which provides a reverse bias at the first p-n junction element; and
m) a second bias element between the second contact and the third contact, which provides a forward bias at the first p-n junction element;
wherein a direction of propagation of light within the p-n junction element and the direction normal to the junction plane forms a tilt angle.

80. The mode-locked tilted cavity laser of claim 79, wherein the cavity, the first multilayer intereference reflector, the second multilayered interference reflector, and the third multilayered interference reflector are optimized such that a resonant optical mode, having a certain wavelength and propagating at a certain tilt angle, has a first value of the leakage losses out of the cavity into the substrate and to at least one contact layer, and any optical modes at a different wavelength or propagating at a different angle have a second value of the leakage losses to the substrate and to at least one contact layer, wherein the second value is larger than the first value for the resonant optical mode; and
wherein the second multilayered interference reflector is optimized such that an electric field strength of the resonant optical mode within the absorbing element provides a bleaching effect.

81. The mode-locked tilted cavity laser of claim 79, wherein the cavity, the first multilayer intereference reflector, the second multilayered interference reflector, and the third multilayered interference reflector are optimized such that a resonant optical mode, having a certain wavelength and propagating at a certain tilt angle, has a first absolute value of the electric field strength in the second p-n junction element, and any optical modes at a different wavelength or propagating at a different angle have a second absolute value of the electric field strength in the second p-n junction element, wherein the second value is smaller than the first value for the resonant optical mode; and
wherein the second multilayered interference reflector is optimized such that an electric field strength of the resonant optical mode within the absorbing element provides a bleaching effect.

82. A semiconductor tilted cavity optoelectronic device comprising:
a) a substrate;
b) a cavity;
c) at least one multilayered interference reflector contiguous with the cavity; and
d) at least one p-n junction element wherein a direction of propagation of light within the p-n junction element and a direction normal to the junction plane forms a tilt angle;
wherein the cavity and the multilayered interference reflector are designed such that a reflectivity dip of the cavity and a reflectivity maximum of the multilayered interference reflector coincide at an optimum tilt angle, and draw apart as the angle changes.

83. The device of claim 82, wherein leaky losses of the tilted optical mode to the substrate and to at least one contact layer are at a minimum at a certain wavelength of light and increase away from this wavelength thus providing wavelength-selective leaky losses of the tilted optical modes such that the semiconductor tilted cavity optoelectronic device is wavelength-stabilized.

84. The device of claim 82, wherein:
an averaged refractive index of the high-finesse cavity and an averaged refractive index of the multilayered interference reflector differ by at least 2%;
the averaged refractive index of the cavity is defined as a square root of a weighted average of a square of the refractive indices of the layers of the cavity; and
the averaged refractive index of the multilayered interference reflector is defined as a square root of a weighted average of a square of the refractive indices of the layers of the multilayered interference reflector.

85. The device of claim 82, wherein a group velocity of propagation of the resonant optical mode in a plane of the p-n junction is slower than a group velocity of the optical mode in a conventional edge-emitting laser formed of the same materials.

86. The device of claim 85, wherein an effective tilt angle of propagation of a resonant tilted optical mode is larger than an angle of a total internal reflection at a semiconductor/air interface by less than 2 degrees.

87. The device of claim 82, wherein the substrate is contiguous with the multilayered interference reflector on a side opposite the cavity.

88. The device of claim 82, wherein the substrate is contiguous with the cavity on a side opposite the multilayered interference reflector.

89. The device of claim 82, wherein a dielectric layer is deposited on top of a structure of the semiconductor to provide a fine tuning of the resonant wavelength.

90. The device of claim 82, further comprising at least one bias element, which provides a bias to the p-n junction element.

91. The device of claim 90, wherein the device is selected from the group consisting of:
a) a diode laser, wherein the p-n junction element comprises a p-n junction, where light is generated when a forward bias is applied;
b) a resonant cavity photodetector, wherein the p-n junction element comprises a p-n junction, to which a reverse bias is applied, and a photocurrent is generated when light is absorbed; and
c) a resonant optical amplifier, wherein the p-n junction element comprises a p-n junction, such that light is amplified when a forward bias is applied.

92. The device of claim 91, wherein the device is a resonant cavity photodetector, further comprising a front facet obtained by cleavage or etching of the substrate, the cavity and at least one multilayered interference reflector, wherein the front facet forms a surface tilted with respect to a plane of the p-n junction at an angle not equal to 90°, and wherein the cavity and the multilayered interference reflector are designed such that light coming in through the front facet is resonantly coupled with a tilted optical mode and is absorbed at the p-n junction to generate a photocurrent.

93. The device of claim 91, further comprising a front facet obtained by cleavage or etching of the substrate, the cavity, and at least one multilayered interference reflector, and a rear facet obtained by cleavage or etching of the substrate, the cavity, and at least one multilayered interference reflector;
wherein the front facet is covered by an antireflecting coating and the rear facet is covered by a highly reflecting coating;
wherein the cavity, the multilayered interference reflector, and the antireflecting coating are designed such that light in a resonant optical mode which impinges at the front facet within the cavity and the multilayered interference reflector undergoes total internal reflection;
wherein light in a resonant optical mode, which has a minimum leakage loss to the substrate compared to optical modes at other wavelengths, has a leaky component, which leaks to the substrate and comes out through the front facet; and
wherein a major part of the optical power coming out of the laser comes out through the leaky component of the resonant optical mode.

94. The device of claim 93, wherein the major part comprises more than 90% of the optical power.

95. The device of claim 93, wherein the front facet is etched to form a surface tilted with respect to a plane of the p-n junction at an angle not equal to 90°, and wherein a direction of the propagation of generated laser light coming out of the device in a leaky mode through the front facet is controlled by a tilt angle of the front facet.

96. The device of claim 82, wherein the p-n junction element is located within the cavity.

97. The device of claim 82, wherein the p-n junction element is located within the multilayered interference reflector.

98. The device of claim 82, wherein at least a portion of the device is composed of a first material selected from the group consisting of:
a) a III-V semiconductor material and
b) an alloy of at least two III-V semiconductor materials.

99. The device of claim 98, wherein the first material is a binary compound comprising a first element and a second element;
wherein the first element is selected from the group consisting of:
i) Al;
ii) Ga; and
iii) In; and
wherein the second element is selected from the group consisting of:
i) N;
ii) P;
iii) As; and
iv) Sb.

100. The device of claim 98, wherein at least a portion of the device is composed of a second material selected from the group consisting of:
a) AlN;
b) GaN;
c) InN; and
d) an alloy of materials selected from the group consisting of AlN; GaN; and InN.

101. The device of claim 87, further comprising an n-contact contiguous with the substrate on a side opposite the multilayered interference reflector.

102. The device of claim 101, further comprising a p-contact contiguous with the cavity on a side opposite the multilayered interference reflector.

103. The device of claim 101, wherein the n-contact is made intentionally rough to enhance a scattering and absorption of light in all optical modes at the n-contact, such that a reflection of a leaky component of the optical mode back to the cavity is suppressed.

104. The device of claim 101, wherein the n-contact is highly reflecting such that the optical modes leaking into the substrate and reaching the n-contact are partially reflected back, which results in an additional modulation of a leaky loss as a function of the wavelength of the optical mode and thus enhances a wavelength selectivity of the tilted cavity optoelectronic device.

105. The device of claim 88, further comprising an n-contact contiguous with the substrate on a side opposite the cavity.

106. The device of claim 105, further comprising a p-contact contiguous with the multilayered interference reflector on a side opposite the cavity.

107. The device of claim 105, wherein the n-contact is intentionally rough to enhance a scattering and absorption of the light in all optical modes at the n-contact, such that a reflection of a leaky component of the optical mode back to the cavity is suppressed.

108. The device of claim 105, wherein the n-contact is highly reflecting such that the optical modes leaking into the substrate and reaching the n-contact are partially reflected back, which results in an additional modulation of a leaky loss as a function of the wavelength of the optical mode and thus enhances a wavelength selectivity of the tilted cavity optoelectronic device.

109. The device of claim 82, wherein the at least one multilayered interference reflector comprises a first multilayered interference reflector and a second multilayered interference reflector.

110. The device of claim 109, wherein the cavity is sandwiched between the first multilayered interference reflector and the second multilayered interference reflector and wherein the substrate is contiguous with the first multilayered interference reflector on a side opposite the cavity.

111. The device of claim 110 further comprising:
a) an n-contact contiguous with the substrate on a side opposite the first multilayered interference reflector; and
b) a p-contact contiguous with the second multilayered interference reflector on a side opposite the cavity.

112. The device of claim 111, wherein the device is a tilted cavity resonant optical amplifier, further comprising two trenches etched in the second multilayered interference reflector;
wherein incoming light comes in through the first trench;
wherein the cavity, the first multilayered interference reflector, and the second multilayered interference reflector are designed such that leaky losses of the tilted optical mode to the substrate and to at least one contact layer are at a minimum at a certain wavelength of light and increase away from this wavelength thus providing wavelength-selective leaky losses of the tilted optical modes such that the tilted cavity resonant optical amplifier is wavelength-stabilized;
wherein incoming light is coupled with the resonant tilted optical mode;
wherein amplified light in the resonant tilted optical mode comes out through the second trench.

113. The device of claim 112, wherein an effective tilt angle of the propagation of the resonant tilted optical mode with respect to the direction normal to the p-n junction plane is less than an angle of the total internal reflection at a semiconductor-air interface.

114. The device of claim 111, wherein the p-n junction element is located within the cavity.

115. The device of claim 111, wherein the p-n junction element is located within the first multilayered interference reflector.

116. The device of claim 111, wherein the p-n junction element is located within the second multilayered interference reflector.

117. The device of claim 82, wherein the multilayered interference reflector further comprises a periodic structure.

118. The device of claim 117, wherein a period of the periodic structure comprises a first layer having a first thickness and a first refractive index and a second layer having a second thickness and a second refractive index.

119. The device of claim 118, wherein a period of the periodic structure further comprises:
a) a third layer having a third thickness and a third refractive index; and
b) a fourth layer having a fourth thickness and a fourth refractive index;
wherein the first refractive index is lower than the second refractive index and the fourth refractive index;
wherein the third refractive index is lower than the second refractive index and the fourth refractive index;
wherein the layers in a period of the periodic structure are placed in a sequence comprising the first layer followed by the second layer followed by the third layer followed by the fourth layer;
wherein the second layer, sandwiched between the first layer and the third layer, forms a first effective high-finesse cavity within the multilayered interference reflector;
wherein the fourth layer, sandwiched between the third layer and a first layer of a neighboring period, forms a second effective high-finesse cavity within the multilayered interference reflector; and
wherein a thickness and a refractive index of each layer, from the first layer through the fourth layer, are selected such that a spectral position of a dip of the first effective high-finesse cavity within the multilayered interference reflector, defined in a reflectivity spectrum of light defined at an optimum tilt angle, is different from a spectral position of a dip of the second effective high-finesse cavity within the multilayered interference reflector, defined in a reflectivity spectrum of light defined at an optimum tilt angle.

120. The device of claim 82, wherein the multilayered interference reflector further comprises:
a sequence of elements, wherein each element comprises at least one first layer having a first refractive index and at least one second layer having a second refractive index wherein the second refractive index is larger than the first refractive index; and
a layered structure comprising at least one third layer in at least one of the elements, which has a smaller thickness than any other layer of the multilayered interference reflector having the same refractive index as the third layer.

121. The device of claim 120, wherein the layered structure comprises a single third layer.

122. The device of claim 121, wherein the third layer has the second refractive index, and is the layer most remote from the cavity.

123. The device of claim 121, wherein the third layer has the first refractive index and is the layer closest to the cavity.

124. The device of claim 120, wherein the layered structure comprises two third layers.

125. The device of claim 124, wherein the first third layer is the most remote layer from the high-finesse cavity and the second third layer is the closest layer to the high-finesse cavity.

126. The device of claim 125, wherein first third layer comprises the second refractive index, and the second third layer comprises the first refractive index.

127. The device of claim 120, wherein the thickness of the third layer is smaller by a factor ranging from 0.3 to 0.8.

128. A method of fine tuning a resonant wavelength of a semiconductor tilted cavity optoelectronic device comprising a substrate, a cavity, at least one multilayered interference reflector contiguous with the cavity, and at least one p-n junction element wherein a direction of propagation of light within the p-n junction element and a direction normal to the junction plane forms a tilt angle, wherein the cavity and the multilayered interference reflector are designed such that a reflectivity dip of the cavity and a reflectivity maximum of the multilayered interference reflector coincide at an optimum tilt angle, and draw apart as the angle changes, and wherein a design is optimized such that the leaky losses of the tilted optical mode to the substrate and at least one of the contact layers is at a minimum at a certain wavelength of light and increases away from this wavelength thus providing wavelength-selective leaky losses of the tilted optical modes such that the semiconductor tilted cavity optoelectronic device is wavelength-stabilized, the method comprising the steps of:
a) epitaxially growing an epitaxial structure;
b) fabricating the tilted cavity optoelectronic device;
c) measuring the resonant wavelength of the fabricated optoelectronic device;
d) calculating a necessary thickness of an additional dielectric layer based on the measured resonant wavelength and on a required resonant wavelength; and
e) depositing the dielectric layer of the thickness calculated in step d) on top of the optoelectronic device.

129. A semiconductor tilted cavity laser comprising:
a) a substrate;
b) a top mirror;
c) a cavity comprising a p-n junction element and located between the top mirror and the substrate wherein the p-n junction element is an active element which generates light when a forward bias is applied;
d) a bottom mirror located between the cavity and the substrate;
e) a front facet formed by cleavage or etching the substrate, the bottom mirror, the cavity, and the top mirror;
f) a rear facet formed by cleavage or etching the substrate, the bottom mirror, the cavity, and the top mirror; and
g) a top contact, wherein a direction of a stripe forming the top contact is tilted in a lateral plane and is rotated such that an angle between the stripe and the facets is different than 90 degrees;
wherein a direction of propagation of light within the p-n junction element and the direction normal to the junction plane forms a tilt angle in a a vertical plane; and
wherein feedback exists only for an optical mode which is additionally tilted in the lateral plane with respect to the direction of the stripe.

130. The light-emitting diode of claim 4, wherein the bottom mirror is a bottom multilayered structure.

131. The light-emitting diode of claim 38, wherein the bottom mirror is a bottom multilayered structure.
